(19) United States
(12) Patent Application Publication
(10) Pub. No.: US 2015/0145120 A1
(43) Pub. Date: May 28, 2015

(54) SEMICONDUCTOR DEVICE HAVING A THROUGH ELECTRODE

(71) Applicant: SK HYNIX INC., Icheon (KR)

(72) Inventor: Dae Woong LEE, Yongin (KR)

(73) Assignee: SK HYNIX INC., Icheon (KR)

(21) Appl. No.: 14/245,988

(22) Filed: Apr. 4, 2014

(30) Foreign Application Priority Data
Nov. 25, 2013 (KR) 10-2013-0143404

(51) Int. Cl. H01L 23/48; H01L 23/00

(52) U.S. Cl. CPC H01L 23/481; H01L 24/13; H01L 2224/13009; H01L 2224/13019; H01L 2924/01029
USPC 257/737

(57) ABSTRACT

A semiconductor device includes a through electrode, a pad, and a bump. The through electrode penetrates a device body of the semiconductor device. The pad is disposed over an end of the through electrode to have a first overlap region and a second overlap region that overlap with a central portion and an edge portion of the end of the through electrode, respectively. The bump is disposed over the pad to contact the second overlap region of the pad without contacting the first overlap region of the pad.

### CROSS-REFERENCE TO RELATED APPLICATION

The present application claims priority under 35 U.S.C. 119(a) to Korean Application No. 10-2013-0143404, filed on Nov. 25, 2013, in the Korean intellectual property Office, which is incorporated herein by reference in its entirety as set forth in full.

### BACKGROUND

1. Technical Field

Embodiments of the present disclosure relate to a semiconductor device and, more particularly, to a semiconductor device having through electrodes.

2. Related Art

As electronic systems including semiconductor chips become smaller and lighter, semiconductor chips that are more highly integrated are increasingly in demand. However, while the size of a semiconductor chip has been gradually reduced, the number of input/output (I/O) pads of the semiconductor chip has been increased. Thus, there may be some limitations in realizing high-performance semiconductor packages using the existing assembly processes. Furthermore, there may be some difficulties in further developing smaller and lighter electronic systems.

Packaging techniques have developed to produce smaller, thinner and lighter semiconductor packages to follow the trend towards smaller and lighter electronic products. For example, a wafer-level packaging process has been proposed to produce compact semiconductor packages. The wafer-level packaging process may include forming a plurality of semiconductor chips on a wafer, encapsulating the plurality of semiconductor chips formed on the wafer, and sawing the wafer to separate the encapsulated semiconductor chips from each other.

Further, a multi-chip package has been a very attractive candidate for increasing a packing density. Recently, through electrodes such as through silicon via (TSV) electrodes penetrating each of the stacked semiconductor chips have been proposed to solve some limitations and/or difficulties in realizing electrical connections between the chips.

### SUMMARY

Various embodiments are directed to semiconductor devices having through electrodes, semiconductor systems including the same, and memory cards including the same.

According to some embodiments, a semiconductor device includes a through electrode, a pad and a bump. The through electrode is disposed to penetrate a device body. The pad is disposed over an end of the through electrode, the pad having an overlap region that overlaps with a central portion of the end of the through electrode. The bump is disposed over the pad without contacting the overlap region of the pad.

According to further embodiments, a semiconductor device includes a through electrode penetrating a device body, a pad disposed on an end of the through electrode to have an overlap region that overlaps with a central portion of the end of the through electrode, and a bump disposed on the pad without any contact the overlap region of the pad. According to further embodiments, a semiconductor device includes a through electrode penetrating a device body, a pad disposed over an end of the through electrode, the pad having an overlap region that overlaps with the through electrode and a non-overlap region that surrounds the overlap region in a plan view, and a bump disposed over the pad. The bump includes a central bump leg disposed over the overlap region of the pad, a plurality of peripheral bump legs disposed over the non-overlap region of the pad, and a bump body disposed on the central bump leg and the plurality of peripheral bump legs.

According to further embodiments, a semiconductor device includes a through electrode and a bump. The through electrode is disposed to penetrate a device body. The bump is disposed to contact an edge portion of an end surface of the through electrode without any contacting a central portion of the end surface of the through electrode.

### BRIEF DESCRIPTION OF THE DRAWINGS

Embodiments of the present invention will become more apparent in view of the attached drawings and accompanying detailed description, in which:

FIG. 1 is a plan view illustrating a semiconductor device according to an embodiment of the present invention;

FIG. 2 is a cross-sectional view taken along a line I-I′ of FIG. 1;

FIG. 3 is a cross-sectional view taken along a line II-II′ of FIG. 1;

FIG. 4 is a plan view illustrating an array of a through electrode and a pad included in the semiconductor device of FIG. 1;

FIG. 5 is a plan view illustrating an array of a through electrode, a pad, and a first insulation layer included in the semiconductor device of FIG. 1;

FIG. 6 is a plan view illustrating an array of a through electrode, a pad, a first insulation layer, and a bump included in the semiconductor device of FIG. 1;

FIG. 7 is a plan view illustrating an array of a through electrode and a pad included in a semiconductor device according to an embodiment of the present invention;

FIG. 8 is a plan view illustrating an array of a through electrode, a pad, and a first insulation layer included in the semiconductor device of FIG. 7;

FIG. 9 is a plan view illustrating an array of a through electrode, a pad, a first insulation layer, and a bump included in the semiconductor device of FIG. 7;

FIG. 10 is a plan view illustrating a semiconductor device according to an embodiment of the present invention;

FIG. 11 is a cross-sectional view taken along a line III-III′ of FIG. 10;

FIG. 12 is a plan view illustrating an array of a through electrode and a pad included in the semiconductor device of FIGS. 10 and 11;

FIG. 13 is a plan view illustrating an array of a through electrode, a pad and a first insulation layer included in the semiconductor device of FIGS. 10 and 11;

FIG. 14 is a plan view illustrating an array of a through electrode, a pad, a first insulation layer, and a bump included in the semiconductor device of FIGS. 10 and 11;

FIG. 15 is a plan view illustrating a semiconductor device according to an embodiment of the present invention;

FIG. 16 is a cross-sectional view taken along a line IV-IV′ of FIG. 15;

FIG. 17 is a plan view illustrating an array of a through electrode and a first insulation layer included in the semiconductor device of FIGS. 15 and 16;

FIG. 18 is a plan view illustrating an array of a through electrode, a first insulation layer and a bump included in the semiconductor device of FIGS. 15 and 16;

FIG. 19 is a plan view illustrating a semiconductor device according to an embodiment of the present invention;

FIG. 20 is a cross-sectional view taken along a line V-V′ of FIG. 19;

FIG. 21 is a plan view illustrating an array of a through electrode and a first insulation layer included in the semiconductor device of FIGS. 19 and 20;

FIG. 22 is a plan view illustrating an array of a through electrode, a first insulation layer, and a bump included in the semiconductor device of FIGS. 19 and 20;

FIG. 23 is a plan view illustrating a semiconductor device according to an embodiment of the present invention;

FIG. 24 is a cross-sectional view taken along a line VI-VI′ of FIG. 23;

FIG. 25 is a cross-sectional view taken along a line VII-VII′ of FIG. 23;

FIG. 26 is a plan view illustrating an array of a through electrode and a pad included in the semiconductor device of FIGS. 23, 24, and 25;

FIG. 27 is a plan view illustrating an array of a through electrode, a pad, and a first insulation layer included in the semiconductor device of FIGS. 23, 24, and 25;

FIG. 28 is a plan view illustrating an array of a through electrode, a pad, a first insulation layer, and a bump included in the semiconductor device of FIGS. 23, 24, and 25;

FIGS. 29, 30, and 31 are cross-sectional views illustrating a method of fabricating a semiconductor device according to an embodiment of the present invention;

FIGS. 32, 33, and 34 are cross-sectional views illustrating a method of fabricating a semiconductor device according to another embodiment of the present invention;

FIG. 35 is a block diagram illustrating an electronic system including a semiconductor device according to an embodiment of the present invention; and

FIG. 36 is a block diagram illustrating another electronic system including a semiconductor device according to an embodiment of the present invention.

### DESCRIPTION OF SPECIFIC EMBODIMENTS

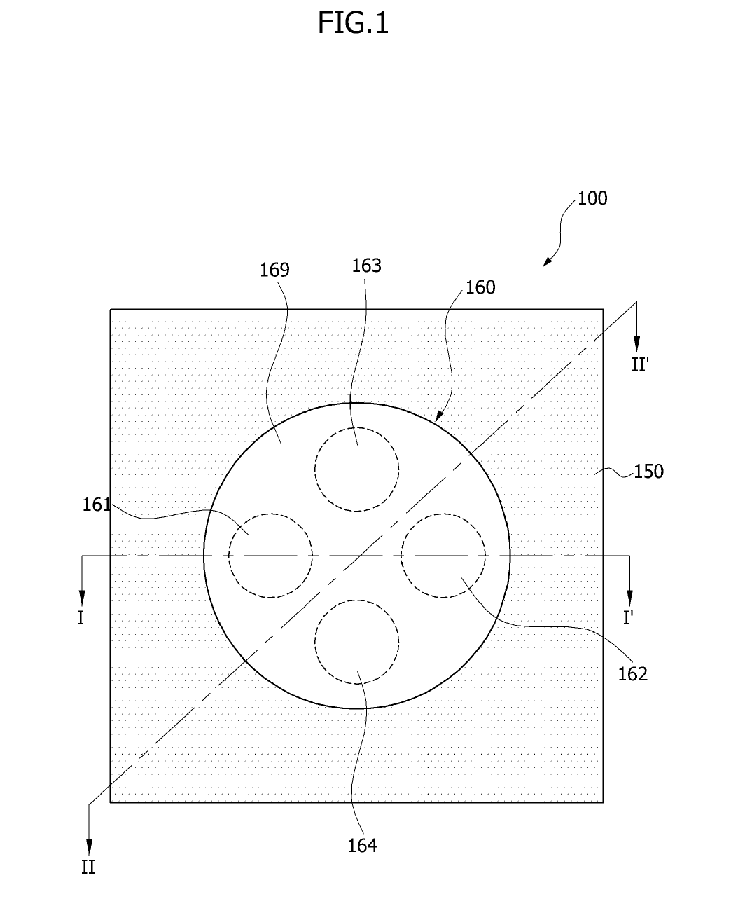

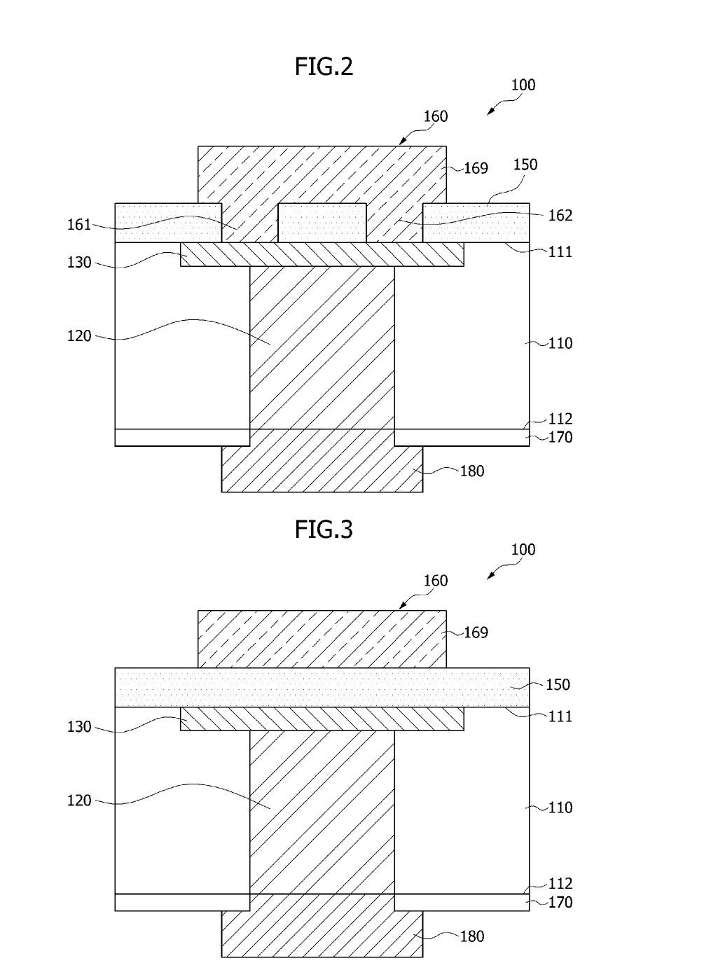

FIG. 1 is a plan view illustrating a semiconductor device 100 according to an embodiment of the present invention. FIG. 2 is a cross-sectional view taken along a line I-I′ of FIG. 1. FIG. 3 is a cross-sectional view taken along a line II-II′ of FIG. 1.

Referring to FIG. 1, the semiconductor device 100 includes a first insulation layer 150 and a bump 160 disposed on the first insulation layer 150. The bump 160 includes a plurality of bump legs, e.g., 161, 162, 163, and 164, and a bump body 169 disposed on the bump legs 161, 162, 163, and 164 and the first insulation layer 150. The bump legs 161, 162, 163, and 164 may extend downward from a bottom surface of the bump body 169. The bump legs 161, 162, 163, and 164 may be disposed to be spaced apart from each other. Although not shown in FIG. 1, the bump legs 161, 162, 163, and 164 may be disposed in respective openings in the first insulation layer 150.

Referring to FIGS. 2 and 3, the semiconductor device 100 includes a device body 110 having a first surface 111 and a second surface 112 which are opposite to each other. Although not shown in the drawings, active elements such as transistors may be disposed in and/or on the device body 110. In addition, passive elements such as resistors and/or capacitors may be disposed in and/or on the device body 110. The device body 110 may be a semiconductor wafer (e.g., a silicon wafer) or a chip body which is obtained by dividing the semiconductor wafer into a plurality of chips through a sawing process. In another embodiment, the device body 110 is composed of another semiconductor material which is different from a silicon material.

A through electrode 120 is disposed to penetrate the device body 110. The through electrode 120 may include at least one metallic material. In an embodiment, the through electrode 120 includes a copper (Cu) material. Although not shown in the drawings, an insulation layer may be disposed between the through electrode 120 and the device body 110 to electrically insulate the through electrode 120 from the device body 110. Furthermore, a barrier layer may be disposed between the through electrode 120 and the device body 110 to prevent metal ions in the through electrode 120 from being diffused into the device body 110. If the barrier layer is formed of an insulation layer, only the barrier layer may be disposed between the through electrode 120 and the device body 110 to electrically insulate the through electrode 120 from the device body 110 and to prevent the metal ions in the through electrode 120 from being diffused into the device body 110.

A pad 130 is disposed in the device body 110 and on a top surface of the through electrode 120. In an embodiment, the pad 130 is adjacent to the first surface 111 of the device body 110. The pad 130 may have a top surface that is disposed at substantially the same level as that of the first surface 111 of the device body 110.

The first insulation layer 150 is disposed on the first surface 111 of the device body 110 and the top surface of the pad 130. In an embodiment, the first insulation layer 150 includes a polymer layer. In another embodiment, the first insulation layer 150 includes a nitride layer or an oxide layer.

The first insulation layer 150 has at least one opening that penetrates the first insulation layer 150 to expose at least one portion of the pad 130. The bump legs 161, 162, 163, and 164 are disposed in respective openings penetrating the first insulation layer 150. Thus, the number of the openings may be equal to the number of the bump legs 161, 162, 163, and 164, and the openings may have substantially the same shape as that of the bump legs 161, 162, 163, and 164. However, embodiments are not limited thereto, and the shape of the bump legs 161, 162, 163, and 164 may not correspond to the shapes of the openings.

A bottom surface of the pad 130 contacts the top surface of the through electrode 120. One of skill in the art will understand that the terms “top” and “bottom” are used herein for convenience of description, to indicate the relationship between surfaces, and should not be construed as limiting. Accordingly, hereinafter, the top surface of the through electrode 120 will be referred to as “a first end surface” and a bottom surface of the through electrode 120 that is opposite to the first end surface will be referred to as “a second end surface”.

The bump 160 is disposed on the first insulation layer 150 to fill the openings. In an embodiment, the bump 160 includes a metallic material such as a copper material. As described with reference to FIG. 1, the bump 160 includes the bump legs 161, 162, 163, and 164 disposed in the openings and the bump body 169 disposed on the bump legs 161, 162, 163, and 164. The bump body 169 covers portions of the first insulation layer 150 around the openings. The bump legs 161, 162, 163, and 164 fill the openings and contact the top surface of the pad 130. The bump legs 161, 162, 163, and 164 may extend downward from the bottom surface of the bump body 169 into the openings. Therefore, the bottom surface of the bump body 169, that is, the top of the bump legs 161, 162, 163, and 164, may be level with the top surface of the first insulation layer 150. Although the present embodiment illustrates four bump legs 161, 162, 163, and 164, embodiments are not limited thereto. In another embodiment, the number of the bump legs may be less or greater than four.

The bump body 169 is disposed on the top surfaces of the bump legs 161, 162, 163 and 164 and on the top surface of the first insulation layer 150. As illustrated in FIG. 2, the bump legs 161, 162, 163, and 164 are disposed between the bump body 169 and the pad 130. In contrast, according to the cross-sectional view of FIG. 3 illustrating a region between the bump legs 161 and 163 and the bump legs 162 and 164, the first insulation layer 150 is disposed between the bump body 169 and the pad 130 in the region.

A second insulation layer 170 is disposed on the second surface 112 of the device body 110 to expose the second end surface of the through electrode 120. In an embodiment, the second insulation layer 170 includes a nitride material or an oxide material. The second end surface of the through electrode 120 is covered with a back-side bump 180. In an embodiment, the back-side bump 180 and the through electrode 120 constitute a single unified body. In another embodiment, the second end surface of the through electrode 120 is covered with another electrical connection member instead of the back-side bump 180.

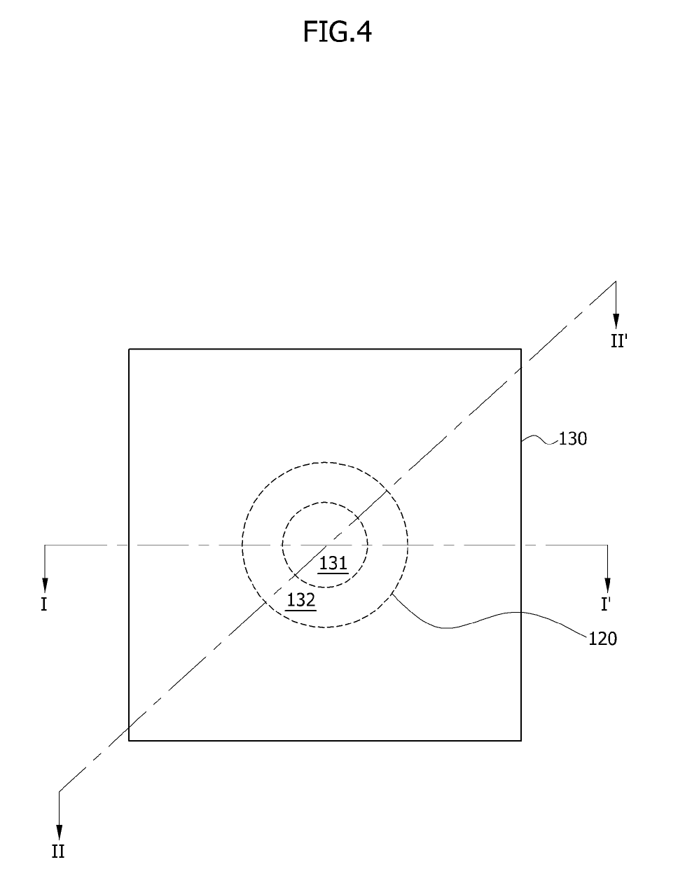

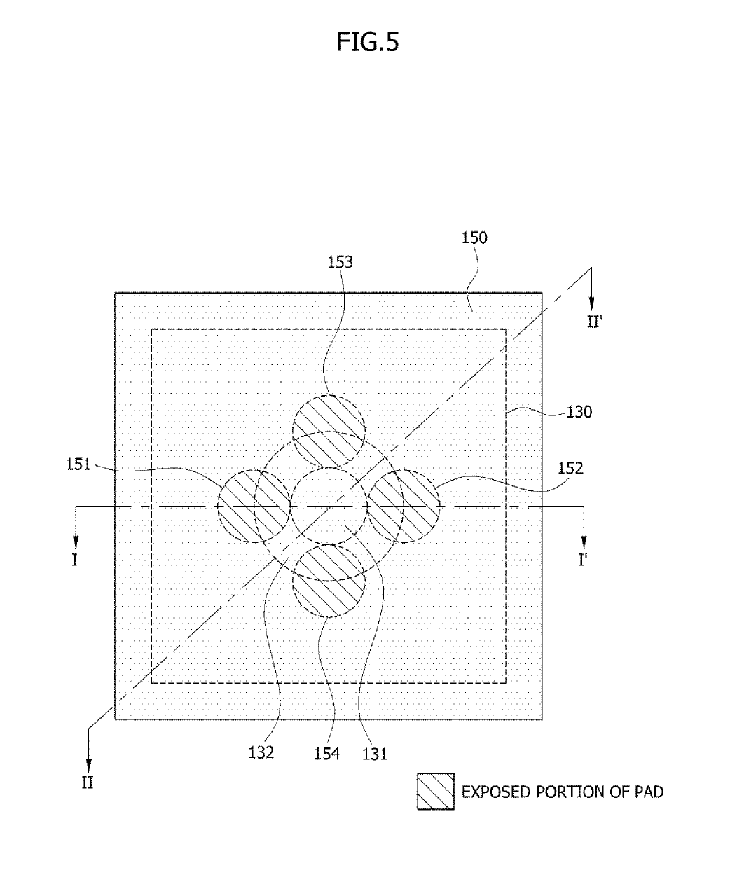

FIG. 4 is a plan view illustrating an array of the through electrode 120 and the pad 130 included in the semiconductor device of FIGS. 1, 2, and 3. A cross-sectional view taken along a line I-I′ of FIG. 4 may be the same as a part of the cross-sectional view of FIG. 2, and a cross-sectional view taken along a line II-II′ of FIG. 4 may be the same as a part of the cross-sectional view of FIG. 3. Referring to FIG. 4, the pad 130 has a rectangular shape in a plan view, and the through electrode 120 has a circular shape in a plan view. However, embodiments are not limited thereto. The pad 130 may have a different shape from the rectangular shape in a plan view, and the through electrode 120 may have a different shape from the circular shape in a plan view.

As described above with reference to FIG. 2, the first end surface of the through electrode 120 contacts the pad 130. A planar area of a surface of the pad 130 is greater than a planar area of the first end surface of the through electrode 120. Thus, the entire first end surface of the through electrode 120 overlaps with a portion of the pad 130 in a plan view. In an embodiment, during fabrication of the semiconductor device 100, the pad 130 is aligned with the through electrode 120 such that the first end surface of the through electrode 120 overlaps with a central portion of the pad 130. However, in another embodiment, the through electrode 120 may not be aligned with the central portion of the pad 130. Embodiments of the present invention may be applicable in either case.

The pad 130 may include a first region that overlaps with the first end surface of the through electrode 120 and a second region that does not overlap with the first end surface of the through electrode 120. In the present embodiment, the first region may be defined as an overlap region. The overlap region may include a first overlap region 131 and a second overlap region 132. The first overlap region 131 may overlap with a central portion of the first end surface of the through electrode 120 and have a circular shape in a plan view. The second overlap region 132 may overlap with an edge portion of the first end surface of the through electrode 120 and have an annular shape surrounding the first overlap region 131 in a plan view. The first and second overlap regions 131 and 132 are defined to distinguish the central portion of the first end surface of the through electrode 120 from the edge portion of the first end surface of the through electrode 120. The central portion (corresponding to the first overlap region 131) of the first end surface of the through electrode 120 is a region from which a relatively strong stress is generated due to a difference between a thermal expansion coefficient of the through electrode 120 and a thermal expansion coefficient of a material of a region adjacent to the through electrode 120 (e.g., device body). That is, the first overlap region 131 contacts the central portion of the first end surface of the through electrode 120 where a thermal stress is strongly generated. A boundary between the central portion and the edge portion of the first end surface of the through electrode 120 may vary depending on a material or a dimension of the through electrode 120.

FIG. 5 is a plan view illustrating an array of the through electrode 120, the pad 130, and the first insulation layer 150 included in the semiconductor device 100 of FIGS. 1, 2, and 3. A cross-sectional view taken along a line I-I′ of FIG. 5 may be the same as a part of the cross-sectional view of FIG. 2, and a cross-sectional view taken along a line II-II′ of FIG. 5 may be the same as a part of the cross-sectional view of FIG. 3.

Referring to FIGS. 1, 2, 3, and 5, the first insulation layer 150 has a plurality of openings 151, 152, 153, and 154 that expose portions of the pad 130. Although FIG. 5 illustrates an embodiment in which each of the openings 151, 152, 153, and 154 has a circular shape, embodiments are not limited thereto. Each of the openings 151, 152, 153, and 154 may have a shape different from the circular shape. The remaining portion of the pad 130, other than the portions of the pad 130 which are exposed by the openings 151, 152, 153, and 154, is covered with the first insulation layer 150. The portions of the pad 130, which are exposed by the openings 151, 152, 153, and 154, directly contacts the bump 160, in particular, the respective bump legs 161, 162, 163, and 164, as described with reference to FIGS. 1, 2, and 3.

The openings 151, 152, 153, and 154 of the first insulation layer 150 are disposed to be spaced apart from each other. FIG. 5 illustrates an embodiment in which the openings 151, 152, 153, and 154 are disposed to be symmetrical to each other with respect to a straight vertical line (not shown) and a straight horizontal line (not shown) which pass through, e.g., a central point of the first overlap region 131. That is, the openings 151, 152, 153, and 154 are disposed to be symmetrical with respect to a central point of the through electrode 120 in a plan view. However, in another embodiment, the openings 151, 152, 153, and 154 are disposed to be asymmetrical to each other.

Furthermore, although FIG. 5 illustrates an embodiment in which the number of openings of the first insulation layer 150 is four, the number of the openings may be less than or greater than four in another embodiment. In any case, the first overlap region 131 of the pad 130 does not overlap with any one of the openings 151, 152, 153, and 154. As a result, the first overlap region 131 of the pad 130 is covered with the first insulation layer 150. In addition, each of the openings 151, 152, 153, and 154 overlaps with at least a portion of the second overlap region 132 of the pad 130. As a result, some portions of the second overlap region 132 of the pad 130 are exposed by the openings 151, 152, 153, and 154.

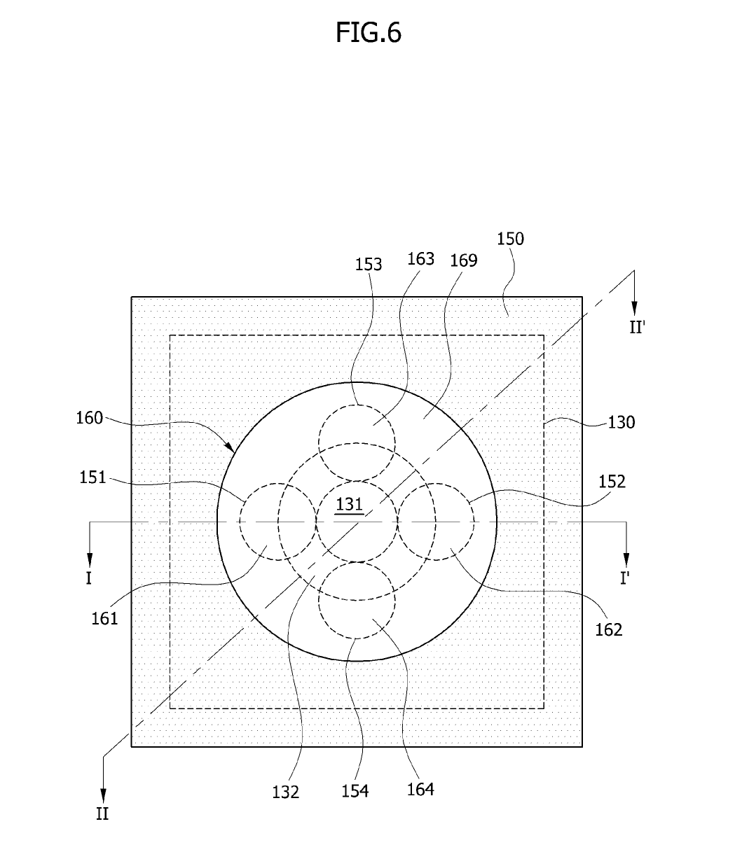

FIG. 6 is a plan view illustrating an array of the through electrode 120, the pad 130, the first insulation layer 150, and the bump 160 included in the semiconductor device 100 of FIGS. 1, 2, and 3. A cross-sectional view taken along a line I-I′ of FIG. 6 may be substantially the same as the cross-sectional view of FIG. 2, and a cross-sectional view taken along a line II-II′ of FIG. 6 may be substantially the same as the cross-sectional view of FIG. 3.

Referring to FIGS. 1, 2, 3, and 6, the bump 160 is disposed on a top surface of the first insulation layer 150 and on top surfaces of the pad 130 that are exposed by the openings 151, 152, 153, and 154. As described with reference to FIGS. 1, 2, and 3, the bump 160 includes the bump legs 161, 162, 163, and 164 disposed in the openings 151, 152, 153, and 154 of the first insulation layer 150 and the bump body 169 disposed on the bump legs 161, 162, 163, and 164 and the first insulation layer 150. In an embodiment, the bump legs 161, 162, 163, and 164 are disposed to be symmetrical to each other with respect to a straight vertical line (not shown) and a horizontal row line (not shown) which pass through, e.g., the central point of the first overlap region 131. That is, the bump legs 161, 162, 163, and 164 may be disposed to be symmetrical with respect to a central point of the through electrode 120 in a plan view. In another embodiment, the bump legs 161, 162, 163, and 164 are disposed to be asymmetrical to each other.

Although FIG. 6 illustrates an embodiment in which the number of the openings and the number of bump legs are four, the number of the openings and the number of the bump legs may be less than or greater than four in another embodiment. The bump legs 161, 162, 163, and 164 downwardly extend from the bottom surface of the bump body 169 into the openings 151, 152, 153, and 154.

According to the present embodiment, the bump body 169 has a circular shape in a plan view, as illustrated in FIG. 6. However, in another embodiment, the bump body 169 may have a different shape from the circular shape in a plan view. Shapes of the bump legs 161, 162, 163, and 164 depend on shapes of the openings 151, 152, 153, and 154, respectively. In an embodiment, if the openings 151, 152, 153, and 154 have a cylindrical shape, the bump legs 161, 162, 163, and 164 have a columnar pillar shape corresponding to the cylindrical shape. Bottom surfaces of the bump legs 161, 162, 163, and 164 respectively contact the top surfaces of the pad 130 that are exposed by the openings 151, 152, 153, and 154. Sidewalls of the bump legs 161, 162, 163, and 164 contact sidewalls of the openings 151, 152, 153, and 154, respectively. Since the bump legs 161, 162, 163, and 164 extend downward from the bottom surface of the bump body 169, an electrical signal applied to the through electrode 120 may be transmitted via a path including the pad 130, the bump legs 161, 162, 163, and 164, and the bump body 169.

As described with reference to FIG. 5, each of the openings 151, 152, 153, and 154 overlaps with at least a portion of the second overlap region 132 of the pad 130, whereas the first overlap region 131 of the pad 130 does not overlap with any one of the openings 151, 152, 153, and 154. As a result, while the bump legs 161, 162, 163, and 164 do not overlap with the first overlap region 131 of the pad 130, each of the bump legs 161, 162, 163, and 164 overlaps with at least a portion of the second overlap region 132 of the pad 130. That is, no bump leg is disposed on the first overlap region 131 of the pad 130, and the first insulation layer 150 is only disposed on the first overlap region 131 of the pad 130. However, the second overlap region 132 of the pad 130 is covered with the first insulation layer 150 and partially overlaps with the bump legs 161, 162, 163, and 164.

The first insulation layer 150 may include a polymer material, and the bump legs 161, 162, 163, and 164 may include a metallic material. Thus, even though a stress is generated from the central portion (corresponding to the first overlap region 131) of the through electrode 120 due to a difference between a thermal expansion coefficient of the through electrode 120 and a thermal expansion coefficient of a material of a region adjacent to the through electrode 120 (e.g., device body), the first insulation layer 150 on the first overlap region 131 may relieve the stress generated from the central portion of the through electrode 120. Moreover, even though a stress is generated from the edge portion (corresponding to the second overlap region 132) of the through electrode 120 due to the difference between the thermal expansion coefficient of the through electrode 120 and the thermal expansion coefficient of the material of the region adjacent to the through electrode 120, the stress generated from the edge portion of the through electrode 120 may be sufficiently relieved by the first insulation layer 150 disposed on the second overlap region 132 because the stress generated from the edge portion of the through electrode 120 is less than the stress generated from the central portion of the through electrode 120.

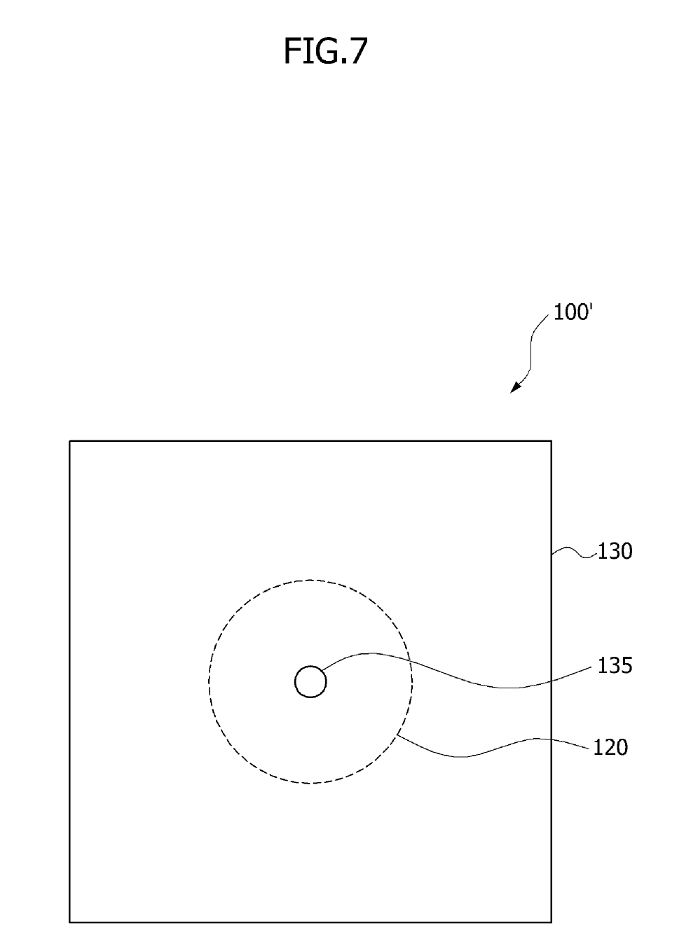

FIG. 7 is a plan view illustrating an array of a through electrode 120 and a pad 130 included in a semiconductor device 100′ according to an embodiment of the present invention. Referring to FIG. 7, the pad 130 of the semiconductor device 100′ has a rectangular shape in a plan view, and the through electrode 120 of the semiconductor device 100′ has a circular shape in a plan view. However, embodiments are not limited thereto. Thus, in another embodiment, the pad 130 of the semiconductor device 100′ may have a shape which is different from the rectangular shape in a plan view, and the through electrode 120 of the semiconductor device 100′ may have a shape which is different from the circular shape in a plan view. The through electrode 120 may be disposed to penetrate a device body of the semiconductor device 100′. One end of the through electrode 120 may contact a bottom surface of the pad 130. A planar area of the pad 130 may be greater than a planar area of the through electrode 120. Thus, the entire top surface of the through electrode 120 may overlap with a portion of the pad 130 in a plan view. In an embodiment, during fabrication of the semiconductor device 100′, the pad 130 is aligned with the through electrode 120 so that a central portion of the pad 130 overlaps with the through electrode 120 in a plan view. However, in another embodiment, the central portion of the pad 130 may not be aligned with the through electrode 120. In either case, the present invention may be applicable.

The pad 130 may include an overlap portion 135 that overlaps with a central portion of the through electrode 120. The central portion of the through electrode 120 is a region from which a relatively strong stress is generated due to a difference between a thermal expansion coefficient of the through electrode 120 and a thermal expansion coefficient of a material of a region adjacent to the through electrode 120 (e.g., device body). The overlap portion 135 may have a circular shape having a predetermined diameter in a plan view, as illustrated in FIG. 7. However, in another embodiment, the overlap portion 135 may have a point shape corresponding to a central point of the through electrode 120 in a plan view.

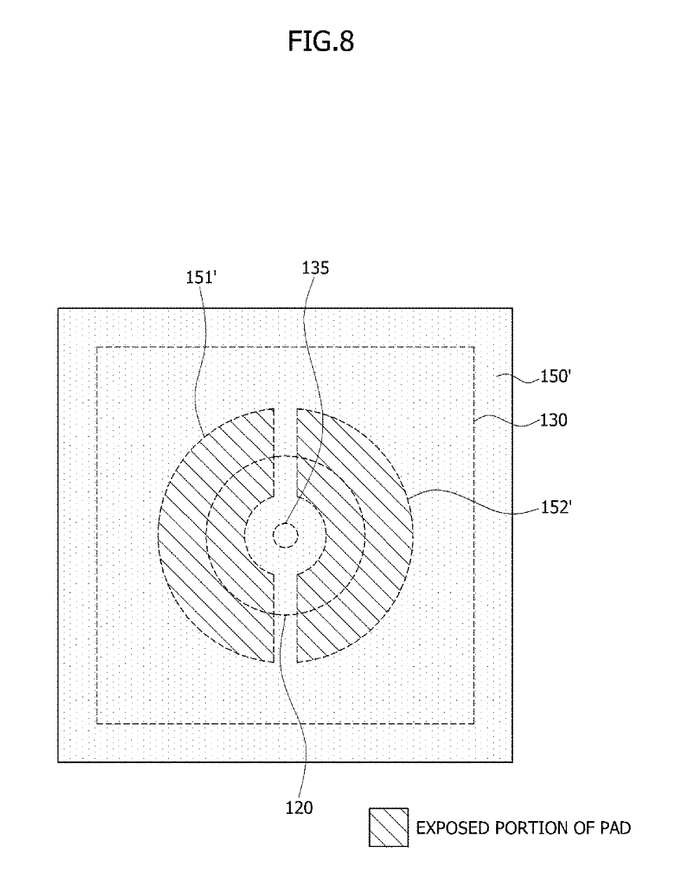

FIG. 8 is a plan view illustrating an array of the through electrode 120, the pad 130, and a first insulation layer 150′ included in the semiconductor device 100′ of FIG. 7. Referring to FIG. 8, the first insulation layer 150′ has a first opening 151′ and a second opening 152′ to expose portions of the pad 130. Each of the first and second openings 151′ and 152′ does not overlap with the overlap portion 135 of the pad 130. A top surface of the pad 130, which is not exposed by the first and second openings 151′ and 152′, is covered with the first insulation layer 150′. The first and second openings 151′ and 152′ are disposed to be symmetrical to each other with respect to a straight vertical line (not shown) therebetween. In another embodiment, the first and second openings 151′ and 152′ may be disposed to be asymmetrical to each other. Furthermore, in another embodiment, each of the first and second openings 151′ and 152′ has a shape in a plan view which is different from a shape illustrated in FIG. 8. In another embodiment, the first insulation layer 150′ has a single opening or three or more openings.

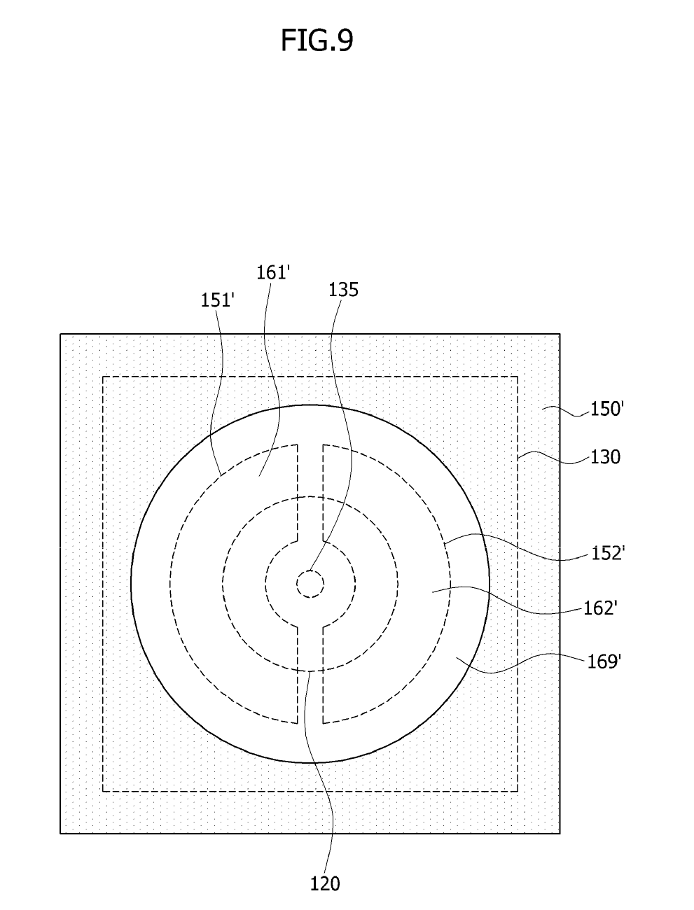

FIG. 9 is a plan view illustrating an array of the through electrode 120, the pad 130, the first insulation layer 150′, and a bump included in the semiconductor device of 100′ of FIG. 7. Referring to FIG. 9, the bump includes a first bump leg 161′ disposed in the first opening 151′, a second bump leg 162′ disposed in the second opening 152′, and a bump body 169′ covering top surfaces of the first and second bump legs 161′ and 162′. The first and second bump legs 161′ and 162′ extend from a bottom surface of the bump body 169′ to the exposed portion of the pad 130.

As described above, the first bump leg 161′ and the second bump leg 162′ are disposed in the first opening 151′ and the second opening 152′, respectively. Thus, the number of the openings is equal to the number of the bump legs, and the openings may have substantially the same shape as that of the bump legs. A top surface of the pad 130, which is not exposed by the first and second openings 151′ and 152′, may be covered with the first insulation layer 150′. Thus, the first insulation layer 150′ may be disposed on the overlap portion 135 of the pad 130. In an embodiment, the first insulation layer 150′ includes a polymer material. In another embodiment, the first insulation layer 150′ includes a nitride material or an oxide material. The first insulation layer 150′ may relieve a physical stress generated from the overlap portion 135 due to a difference between a thermal expansion coefficient of the through electrode 120 and a thermal expansion coefficient of a material of a region adjacent to the through electrode 120 (e.g., device body). Although FIG. 9 illustrates an embodiment in which the bump body 169′ has a circular shape in a plan view, a shape of the bump body 169′ is not limited thereto. That is, in another embodiment, the bump body 169′ has a shape which is different from the circular shape in a plan view.

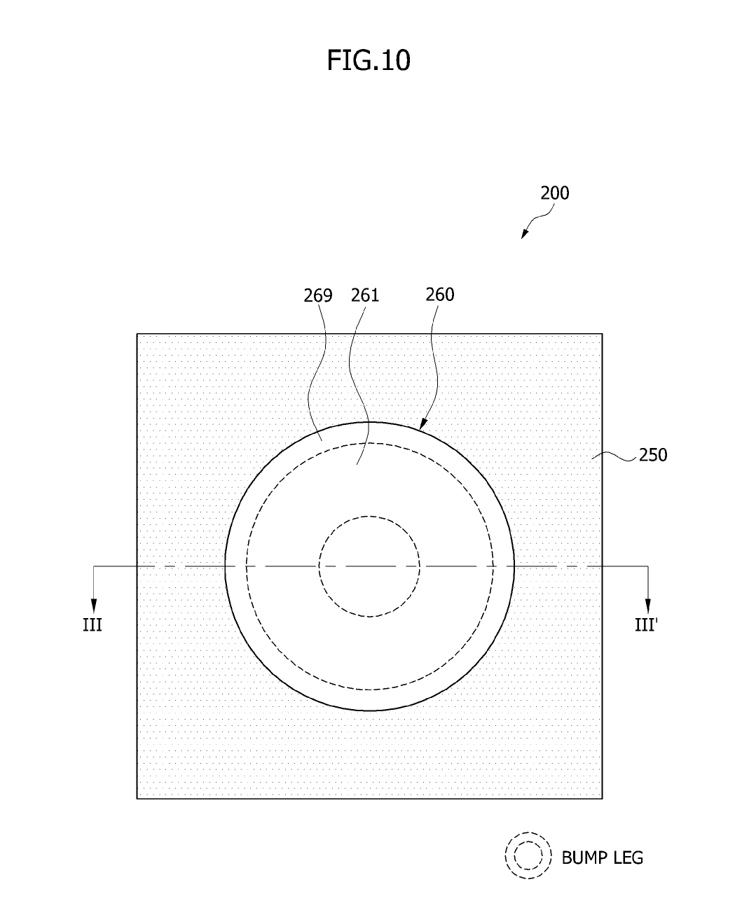

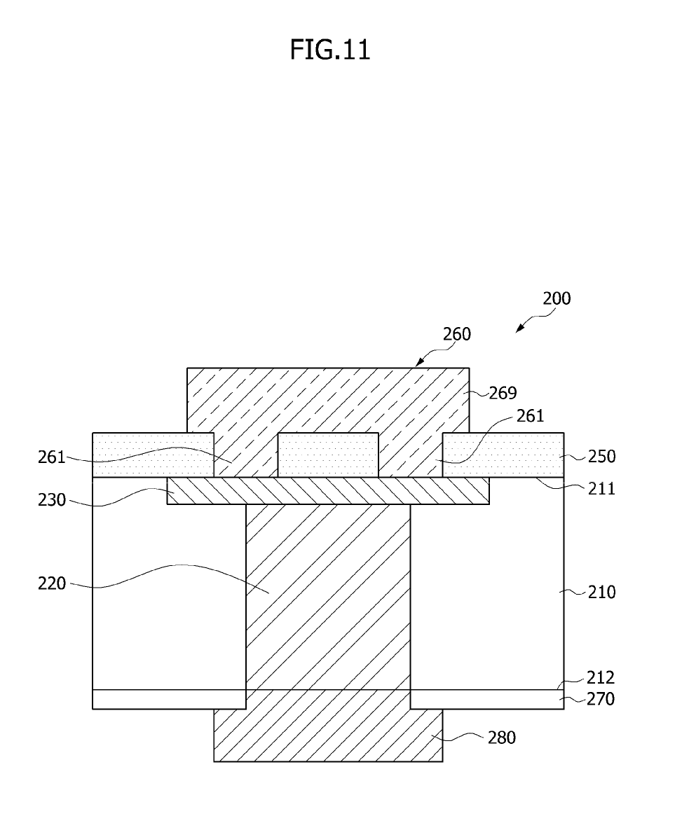

FIG. 10 is a plan view illustrating a semiconductor device 200 according to an embodiment of the present invention, and FIG. 11 is a cross-sectional view taken along a line III-III′ of FIG. 10. Referring to FIG. 10, the semiconductor device 200 includes a first insulation layer 250 and a bump 260 disposed on the first insulation layer 250. The bump 260 includes a bump leg 261 and a bump body 269. The bump body 269 is disposed on the bump leg 261 and a portion of the first insulation layer 250. The bump leg 261 may extend downward from a bottom surface of the bump body 269. In the present embodiment, the bum leg 261 includes a single bump leg. That is, the bump leg 261 has an annular shape in a plan view, as illustrated by dotted lines in FIG. 10. The bump leg 261 is disposed in an opening (not shown) of the first insulation layer 250.

Referring to FIGS. 10 and 11, the semiconductor device 200 further includes a device body 210 having a first surface 211 and a second surface 212 which are opposite to each other. Although not shown in the drawings, active elements such as transistors may be disposed in and/or on the device body 210. In addition, passive elements such as resistors and/or capacitors may be disposed in and/or on the device body 210. The device body 210 may be a semiconductor wafer (e.g., a silicon wafer) or a chip body which is obtained by dividing the semiconductor wafer into a plurality of chips through a sawing process. In another embodiment, the device body 210 is composed of another semiconductor material which is different from a silicon material.

A through electrode 220 is disposed to penetrate the device body 210. The through electrode 220 may include at least one metallic material. In an embodiment, the through electrode 220 includes a copper (Cu) material. Although not shown in the drawings, an insulation layer may be disposed between the through electrode 220 and the device body 210 to electrically insulate the through electrode 220 from the device body 210. Furthermore, a barrier layer may be disposed between the through electrode 220 and the device body 210 to prevent metal ions in the through electrode 220 from being diffused into the device body 210. If the barrier layer is formed of an insulation layer, only the barrier layer may be disposed between the through electrode 220 and the device body 210 to electrically insulate the through electrode 220 from the device body 210 and to prevent the metal ions in the through electrode 220 from being diffused into the device body 210.

A pad 230 is disposed in the device body 210 and on a top surface of the through electrode 220. The pad 230 is adjacent to the first surface 211 of the device body 210. The pad 230 may have a top surface that is disposed at substantially the same level as that of the first surface 211 of the device body 210.

The first insulation layer 250 is disposed on the first surface 211 of the device body 210 and the top surface of the pad 230. In an embodiment, the first insulation layer 250 includes a polymer layer. In another embodiment, the first insulation layer 250 includes a nitride layer or an oxide layer.

The first insulation layer 250 has an opening to expose a portion of the pad 230. The opening may have substantially the same shape as that of the bump leg 261. A bottom surface of the pad 230 contacts the top surface of the through electrode 220. In the present embodiment, the top surface of the through electrode 220 will be referred to as “a first end surface” and a bottom surface of the through electrode 220 that is opposite to the first end surface will be referred to as “a second end surface”.

The bump 260 is disposed on the first insulation layer 250 to fill the opening. In an embodiment, the bump 260 includes a metallic material such as a copper material. As described with reference to FIG. 10, the bump 260 includes the bump leg 261 disposed in the opening and the bump body 269 disposed on the bump leg 261 and covering portions of the first insulation layer 250 around the opening. The bump leg 261 fills the opening and contacts the top surface of the pad 230 that is exposed by the opening. A top surface of the bump leg 261 may be level with the top surface of the first insulation layer 250. The bump body 269 is disposed on the top surface of the bump leg 261 and on the top surface of the first insulation layer 250. Thus, as illustrated in FIG. 11, the bump leg 261 is disposed between the bump body 269 and the pad 230. Meanwhile, in a certain region which is laterally adjacent to the bump leg 261, the first insulation layer 250 is disposed between the bump body 269 and the pad 230.

A second insulation layer 270 is disposed on the second surface 212 of the device body 210 to expose the second end surface of the through electrode 220. In an embodiment, the second insulation layer 270 includes a nitride material or an oxide material. The second end surface of the through electrode 220 is covered with a back-side bump 280. In an embodiment, the back-side bump 280 and the through electrode 220 constitute a single unified body without any heterogeneous junction therebetween. In another embodiment, the second end surface of the through electrode 220 is covered with another electrical connection member instead of the back-side bump 280.

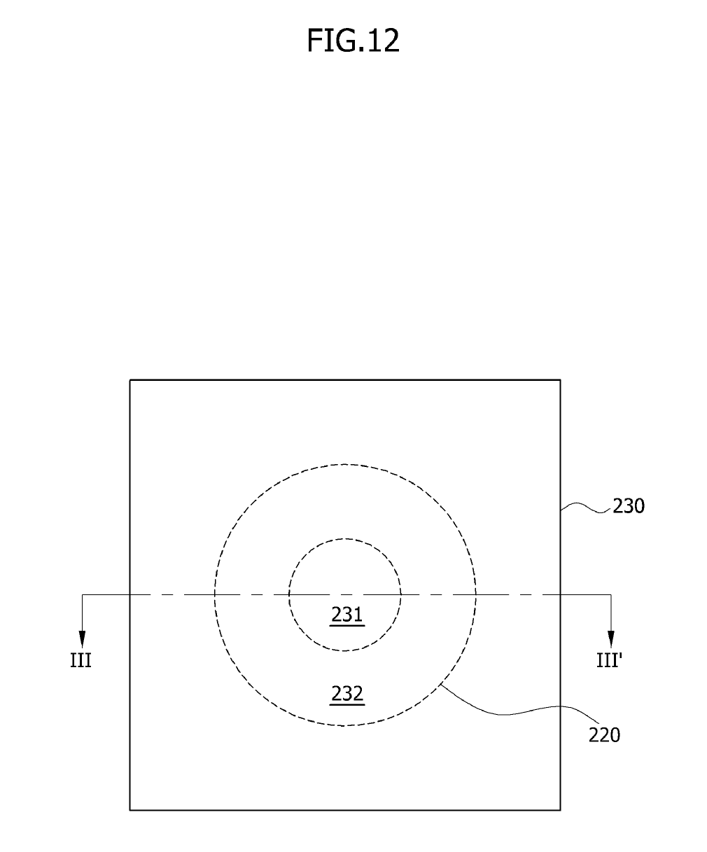

FIG. 12 is a plan view illustrating an array of the through electrode 220 and the pad 230 included in the semiconductor device 200 of FIGS. 10 and 11. A cross-sectional view taken along a line III-III′ of FIG. 12 may be the same as a part of the cross-sectional view of FIG. 11. Referring to FIGS. 10, 11, and 12, the pad 230 has a rectangular shape in a plan view, and the through electrode 220 has a circular shape in a plan view. However, embodiments are not limited thereto. The pad 230 may have a different shape from the rectangular shape in a plan view, and the through electrode 220 may have a different shape from the circular shape in a plan view.

As described above with reference to FIG. 11, the first end surface of the through electrode 220 contacts the pad 230. A planar area of a surface of the pad 230 is greater than a planar area of the first end surface of the through electrode 220. Thus, the entire first end surface of the through electrode 220 overlaps with a portion of the pad 230 in a plan view. In an embodiment, during fabrication of the semiconductor device 200, the pad 230 is aligned with the through electrode 220 so that a central portion of the pad 230 overlaps with the first end surface of the through electrode 220. However, in other embodiments, the central portion of the pad 230 may not be aligned with the through electrode 220. In either case, the present invention may be applicable.

The pad 230 may include a first region that overlaps with the first end surface of the through electrode 220 and a second region that does not overlap with the first end surface of the through electrode 220. In the present embodiment, the first region may be defined as an overlap region. The overlap region may include a first overlap region 231 and a second overlap region 232. The first overlap region 231 may overlap with a central portion of the first end surface of the through electrode 220 and have a circular shape in a plan view. The second overlap region 232 may overlap with an edge portion of the first end surface of the through electrode 220 and have an annular shape surrounding the first overlap region 231 in a plan view. The first and second overlap regions 231 and 232 are defined to distinguish the central portion of the first end surface of the through electrode 220 from the edge portion of the first end surface of the through electrode 220. The central portion (corresponding to the first overlap region 231) of the first end surface of the through electrode 220 is a region from which a relatively strong stress is generated due to a difference between a thermal expansion coefficient of the through electrode 220 and a thermal expansion coefficient of a material of a region adjacent to the through electrode 220 (e.g., device body). That is, the first overlap region 231 contacts the central portion of the first end surface of the through electrode 220 where a thermal stress is strongly generated. A boundary between the central portion and the edge portion of the first end surface of the through electrode 220 may vary depending on a material or a dimension of the through electrode 220.

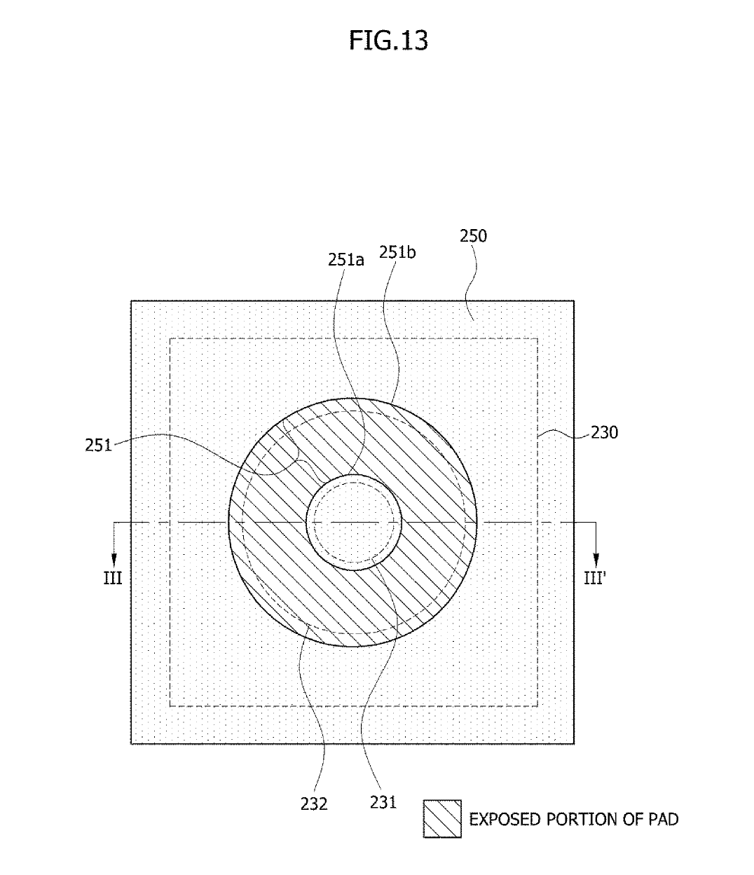

FIG. 13 is a plan view illustrating an array of the through electrode 220, the pad 230, and the first insulation layer 250 included in the semiconductor device 200 of FIGS. 10 and 11. A cross-sectional view taken along a line III-III′ of FIG. 13 may be the same as a part of the cross-sectional view of FIG. 11. Referring to FIGS. 10, 11, and 13, the first insulation layer 250 has an opening 251 to expose a portion of the pad 230. The opening 251 has an annular shape in a plan view. Thus, the portion of the pad 230 exposed by the opening 251 may also have an annular shape in a plan view. The remaining portion of the pad 230 other than the portion of the pad 230 exposed by the opening 251 is covered with the first insulation layer 250. The portion of the pad 230 exposed by the opening 251 directly contacts the bump 260, in particular, the bump leg 261. The opening 251 of the first insulation layer 250 may not overlap with the first overlap region 231 of the pad 230 in a plan view. However, the opening 251 of the first insulation layer 250 overlaps with at least a portion of the second overlap region 232 of the pad 230. Thus, only a portion of the second overlap region 232 of the pad 230 is exposed by the opening 251. In an embodiment, the entire second overlap region 232 of the pad 230 is exposed by the opening 251. In such a case, an inner circle 251a of the opening 251 having an annular shape may be close to a circle defining the first overlap region 231 in a plan view, and an outer circle 251b of the opening 251 may be close to a circle defining the second overlap region 232 in a plan view. In the present embodiment, the inner circle 251a has a diameter slightly greater than that of the first overlap region 231, and the outer circle 251b has a diameter slightly greater than that of the second overlap region 232.

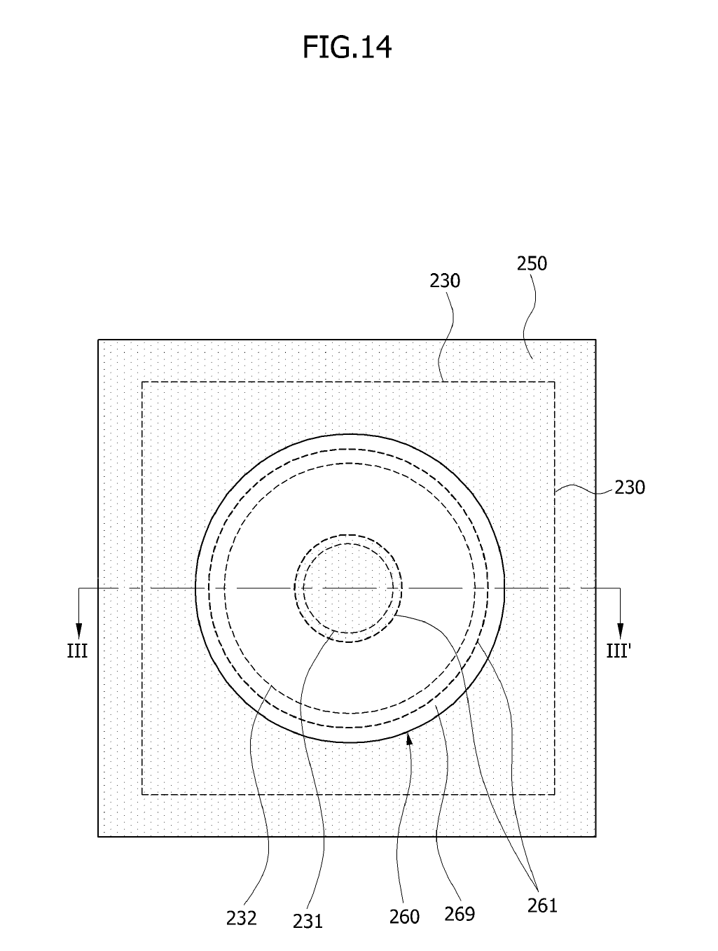

FIG. 14 is a plan view illustrating an array of the through electrode 220, the pad 230, the first insulation layer 250, and the bump 260 included in the semiconductor device 200 of FIGS. 10 and 11. A cross-sectional view taken along a line III-III′ of FIG. 14 may be substantially the same as the cross-sectional view of FIG. 11. Referring to FIGS. 10, 11, 13, and 14, the bump 260 is disposed on a top surface of the first insulation layer 250 and on a top surface of the pad 230 that is exposed by the opening 251. As described with reference to FIGS. 10 and 11, the bump 260 includes the bump leg 261 disposed in the opening 251 of the first insulation layer 250 and the bump body 269 disposed on the bump leg 261 and the first insulation layer 250. The bump leg 261 may extend downward from a bottom surface of the bump body 269 into the opening 251.

According to the present embodiment, the bump body 269 has a circular shape in a plan view, as illustrated in FIG. 10. However, in another embodiment, the bump body 269 has a different shape from the circular shape in a plan view. A shape of the bump leg 261 depends on a shape of the opening 251. In an embodiment, if the opening 251 has an annular shape, the bump leg 261 also has the annular shape. A bottom surface of the bump leg 261 contacts the top surface of the pad 230 that is exposed by the opening 251. An inner sidewall and an outer sidewall of the bump leg 261 contact an inner sidewall and an outer sidewall of the opening 251, respectively. Since the bump leg 261 extends downward from the bottom surface of the bump body 269, an electrical signal applied to the through electrode 220 may be transmitted via a path including the pad 230, the bump legs 261, and the bump body 269.

As described with reference to FIG. 13, the opening 251 overlaps with at least a portion of the second overlap region 232 of the pad 230, whereas the opening 251 does not overlap with the first overlap region 231 of the pad 230. Thus, the bump leg 261 also does not overlap with the first overlap region 231 of the pad 230. The bump leg 261 filling the opening 251 overlaps with at least a portion of the second overlap region 232 of the pad 230. That is, the bump leg 261 does not overlap with the first overlap region 231 of the pad 230, and the first insulation layer 250 is disposed on the first overlap region 231 of the pad 230. The second overlap region 232 of the pad 230 is covered with the bump leg 261 and partly covered with the first insulation layer 250. The first insulation layer 250 may include a polymer material, and the bump leg 261 may include a metallic material. Thus, even though a stress is generated from a central portion (corresponding to the first overlap region 231) of the through electrode 220 due to a difference between a thermal expansion coefficient of the through electrode 220 and a thermal expansion coefficient of a material of a region adjacent to the through electrode 220, the first insulation layer 250 on the first overlap region 231 may relieve the stress generated from the central portion of the through electrode 220 (e.g., device body).

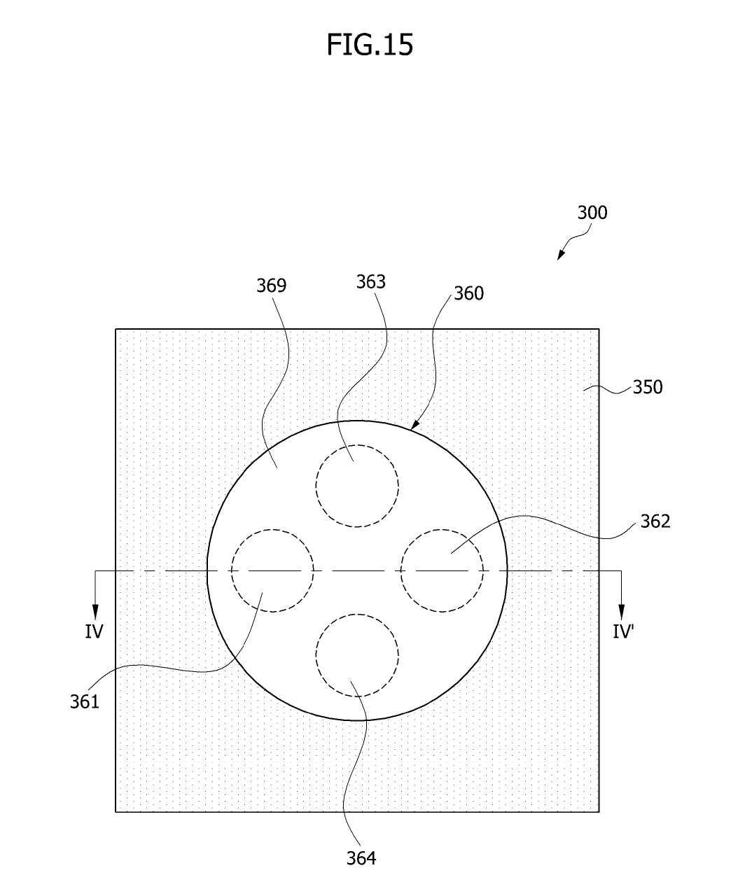

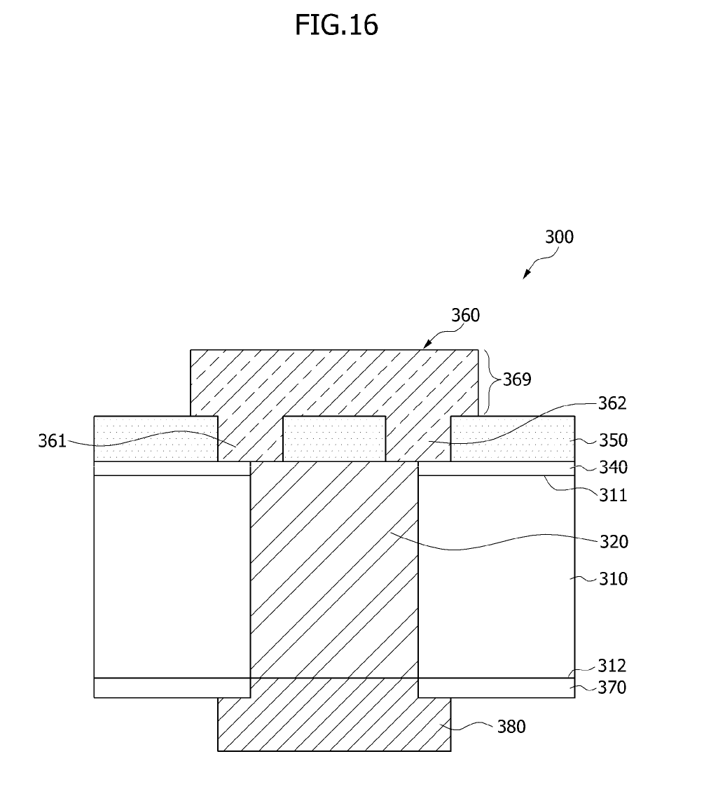

FIG. 15 is a plan view illustrating a semiconductor device 300 according to an embodiment of the present invention, and FIG. 16 is a cross-sectional view taken along a line IV-IV′ of FIG. 15. Referring to FIG. 15, the semiconductor device 300 includes a first insulation layer 350 and a bump 360 disposed on the first insulation layer 350. The bump 360 includes a plurality of bump legs 361, 362, 363, and 364 and a bump body 369. The bump body 369 is disposed on the bump legs 361, 362, 363, and 364 and a portion of the first insulation layer 350. The bump legs 361, 362, 363, and 364 may extend downward from a bottom surface of the bump body 369. The bump legs 361, 362, 363, and 364 are disposed to be spaced apart from each other. Although not shown in FIG. 15, the bump legs 361, 362, 363, and 364 may be disposed in respective openings of the first insulation layer 350.

Referring to FIGS. 15 and 16, the semiconductor device 300 further includes a device body 310 having a first surface 311 and a second surface 312, which are opposite to each other. Although not shown in the drawings, active elements such as transistors may be disposed in and/or on the device body 310. In addition, passive elements such as resistors and/or capacitors may be disposed in and/or on the device body 310. The device body 310 may be a semiconductor wafer (e.g., a silicon wafer) or a chip body which is obtained by dividing the semiconductor wafer into a plurality of chips through a sawing process. In another embodiment, the device body 310 is composed of another semiconductor material which is different from a silicon material.

A protection layer pattern 340 is disposed on the first surface 311 of the device body 310. A through electrode 320 is disposed to penetrate the device body 310 and the protection layer pattern 340. The through electrode 320 may include at least one metallic material. In an embodiment, the through electrode 320 includes a copper (Cu) material. Although not shown in the drawings, an insulation layer may be disposed between the through electrode 320 and the device body 310 to electrically insulate the through electrode 320 from the device body 310. Furthermore, a barrier layer may be disposed between the through electrode 320 and the device body 310 to prevent metal ions in the through electrode 320 from being diffused into the device body 310. If the barrier layer is formed of an insulation layer, only the barrier layer may be disposed between the through electrode 320 and the device body 310 to electrically insulate the through electrode 320 from the device body 310 and to prevent the metal ions in the through electrode 320 from being diffused into the device body 310.

A first end surface of the through electrode 320 is exposed at substantially the same level as that of a top surface of the protection layer pattern 340. The first insulation layer 350 is disposed on the top surface of the protection layer pattern 340 and the first end surface of the through electrode 320. The first insulation layer 350 has a plurality of openings where the bump legs 361, 362, 363, and 364 are to be formed. In an embodiment, the first insulation layer 350 includes a polymer layer. In another embodiment, the first insulation layer 350 includes a nitride layer or an oxide layer.

As described with reference to FIG. 15, the bump 360 includes the plurality of bump legs 361, 362, 363, and 364 and the bump body 369. Each of the bump legs 361, 362, 363, and 364 penetrates the first insulation layer 350 through the openings to contact a portion of the first end surface of the through electrode 320. In an embodiment, the bump 360 includes a metallic material such as a copper material.

The bump legs 361, 362, 363 and 364 fill the openings of the first insulation layer 350 and contact at least portions of the through electrode 320 exposed by the openings. Top surfaces of the bump legs 361, 362, 363, and 364 may level with a top surface of the first insulation layer 350. The bump body 369 is disposed to fully cover the top surfaces of the bump legs 361, 362, 363 and 364. As illustrated in FIG. 16, the bump legs 361, 362, 363, and 364 are disposed between the bump body 369 and the through electrode 320. However, in regions between the bump legs 361, 362, 363, and 364, the first insulation layer 350 is disposed between the bump body 369 and the through electrode 320.

Although FIG. 16 illustrates an embodiment in which each of the bump legs 361, 362, 363, and 364 contacts both the through electrode 320 and the protection layer pattern 340, embodiments are not limited thereto. In another embodiment, a bottom surface of each of the bump legs 361, 362, 363, and 364 contacts only the through electrode 320.

A second insulation layer 370 is disposed on the second surface 312 of the device body 310, and is disposed to expose a second end surface of the through electrode 320. In an embodiment, the second insulation layer 370 includes a nitride material or an oxide material. The second end surface of the through electrode 320 is covered with a back-side bump 380. In an embodiment, the back-side bump 380 and the through electrode 320 constitute a single unified body without any heterogeneous junction therebetween. In another embodiment, the second end surface of the through electrode 320 is covered with another electrical connection member instead of the back-side bump 380.

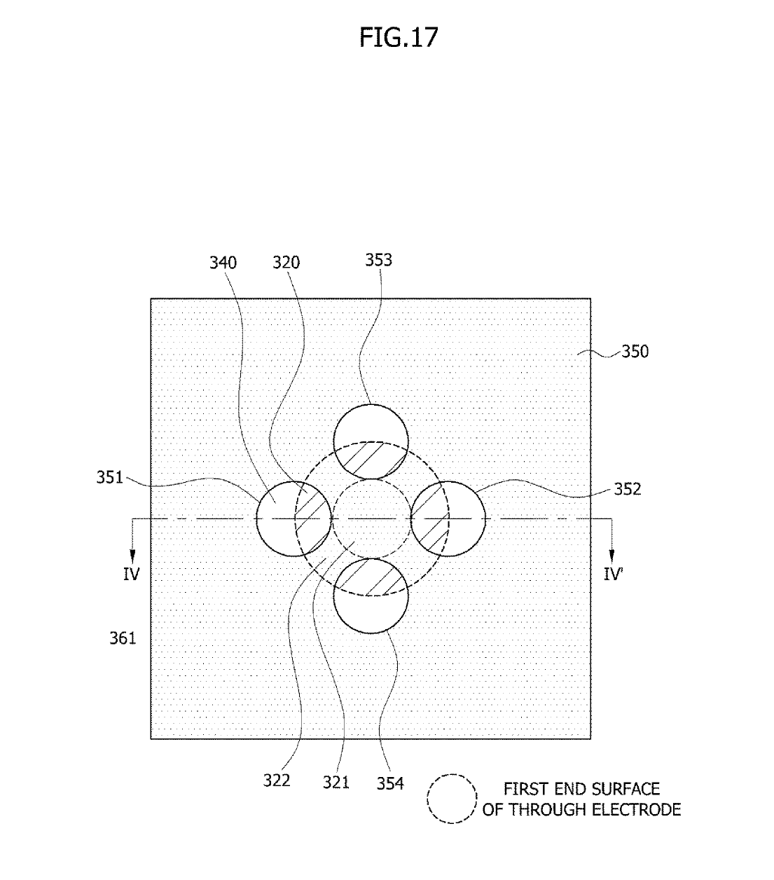

FIG. 17 is a plan view illustrating an array of the through electrode 320 and the first insulation layer 350 included in the semiconductor device 300 of FIGS. 15 and 16. A cross-sectional view taken along a line IV-IV′ of FIG. 17 may be the same as a part of the cross-sectional view of FIG. 16. As illustrated in FIG. 17, the first end surface of the through electrode 320 has a circular shape in a plan view. However, in another embodiment, the first end surface of the through electrode 320 has a different shape from the circular shape in a plan view. The first end surface of the through electrode 320 includes a central portion 321 and an edge portion 322. The central portion 321 has a circular shape including a central point of the first end surface of the through electrode 320 in a plan view, and the edge portion 322 has an annular shape surrounding the central portion 321 in a plan view.

The first insulation layer 350 has a plurality of openings 351, 352, 353, and 354 which are spaced apart from each other. Although FIG. 17 illustrates an embodiment in which each of the openings 351, 352, 353, and 354 has a circular shape, embodiments are not limited thereto. In another embodiment, each of the openings 351, 352, 353, and 354 has a shape which is different from the circular shape. The central portion 321 of the through electrode 320 does not overlap with any one of the openings 351, 352, 353, and 354 in a plan view. Each of the openings 351, 352, 353, and 354 exposes a portion of the edge portion 322 of the through electrode 320. Thus, the central portion 321 of the through electrode 320 is covered with the first insulation layer 350. The edge portion 322 between the openings 351, 352, 353, and 354 is also covered with the first insulation layer 350.

FIG. 17 illustrates an embodiment in which the openings 351, 352, 353, and 354 are disposed to be symmetrical to each other with respect to a straight vertical line (not shown) and a straight horizontal line (not shown) which pass through a central point of the through electrode 320. That is, the openings 351, 352, 353, and 354 are disposed to be symmetric to each other with respect to the central point of the through electrode 320 in a plan view. However, embodiments are not limited thereto. In another embodiment, the openings 351, 352, 353, and 354 are disposed to be asymmetrical to each other. Furthermore, although FIG. 17 illustrates an embodiment in which the number of openings is four, the number of the openings may be less than or greater than four in another embodiment.

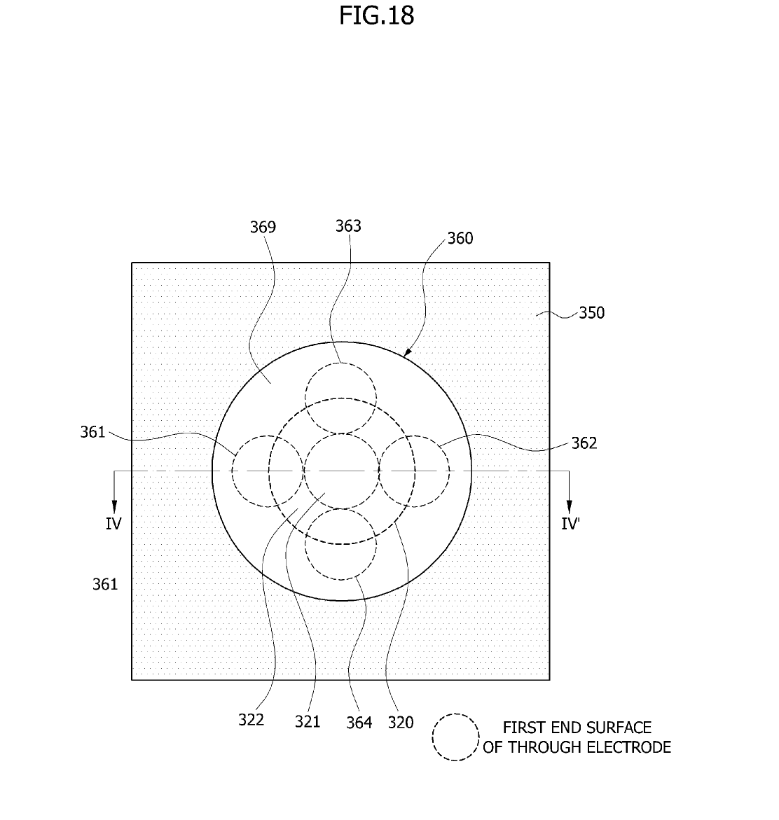

FIG. 18 is a plan view illustrating an array of the through electrode 320, the first insulation layer 350, and the bump 360 included in the semiconductor device 300 of FIGS. 15 and 16. A cross-sectional view taken along a line IV-IV′ of FIG. 18 may be substantially the same as the cross-sectional view of FIG. 16. As illustrated in FIGS. 16, 17, and 18, the bump 360 includes the bump legs 361, 362, 363, and 364, which are disposed on portions of the protection layer pattern 340 and portions of the through electrode 320 exposed by the openings 351, 352, 353, and 354, and the bump body 369, which is disposed on the bump legs 361, 362, 363, and 364 and a portion of the first insulation layer 350.

The bump legs 361, 362, 363, and 364 extend from a bottom surface of the bump body 369. A shape of each of the bump legs 361, 362, 363, and 364 is defined by a shape of a corresponding one of the openings 351, 352, 353, and 354. In an embodiment, if the openings 351, 352, 353, and 354 have a cylindrical shape, the bump legs 361, 362, 363, and 364 have a columnar pillar shape corresponding to the cylindrical shape. Each of the bump legs 361, 362, 363, and 364 contacts a portion of the protection layer pattern 340 and a portion of the through electrode 320, which are exposed by a corresponding one of the openings 351, 352, 353, and 354. Sidewalls of the bump legs 361, 362, 363, and 364 contact sidewalls of the openings 351, 352, 353, and 354, respectively. Since the bump legs 361, 362, 363, and 364 extend downward from the bottom surface of the bump body 369, an electrical signal applied to the through electrode 320 may be transmitted via a path including the bump legs 361, 362, 363, and 364 and the bump body 369.

As described with reference to FIG. 17, each of the openings 351, 352, 353, and 354 overlaps with at least a portion of the edge portion 322 of the through electrode 320, whereas none of the openings 351, 352, 353, and 354 overlaps with the central portion 321 of the through electrode 320. As a result, while none of the bump legs 361, 362, 363, and 364 contacts the central portion 321 of the through electrode 320, each of the bump legs 361, 362, 363, and 364 contacts at least a portion of the edge portion 322 of the through electrode 320. That is, no bump leg is disposed on the central portion 321 of the through electrode 320, and thus only the first insulation layer 350 is disposed on the central portion 321 of the through electrode 320. However, the edge portion 322 of the through electrode 320 is covered with the first insulation layer 350 as well as the bump legs 361, 362, 363 and 364.

The first insulation layer 350 may include a polymer material, and the bump legs 361, 362, 363, and 364 may include a metallic material. Thus, even though a stress is generated from the central portion 321 of the through electrode 320 due to a difference between a thermal expansion coefficient of the through electrode 320 and a thermal expansion coefficient of a material of a region adjacent to the through electrode 320 (e.g., device body), the first insulation layer 350 on the central portion 321 of the through electrode 320 may relieve the stress generated from the central portion 321 of the through electrode 320. Moreover, even though a stress is generated from the edge portion 322 of the through electrode 320 due to the difference between the thermal expansion coefficient of the through electrode 320 and the thermal expansion coefficient of the material of the region adjacent to the through electrode 320, the stress generated from the edge portion 322 of the through electrode 320 may be sufficiently relieved by the first insulation layer 350 disposed on the edge portion 322 of the through electrode 320 because the stress generated from the edge portion 322 of the through electrode 320 is less than the stress generated from the central portion 321 of the through electrode 320.

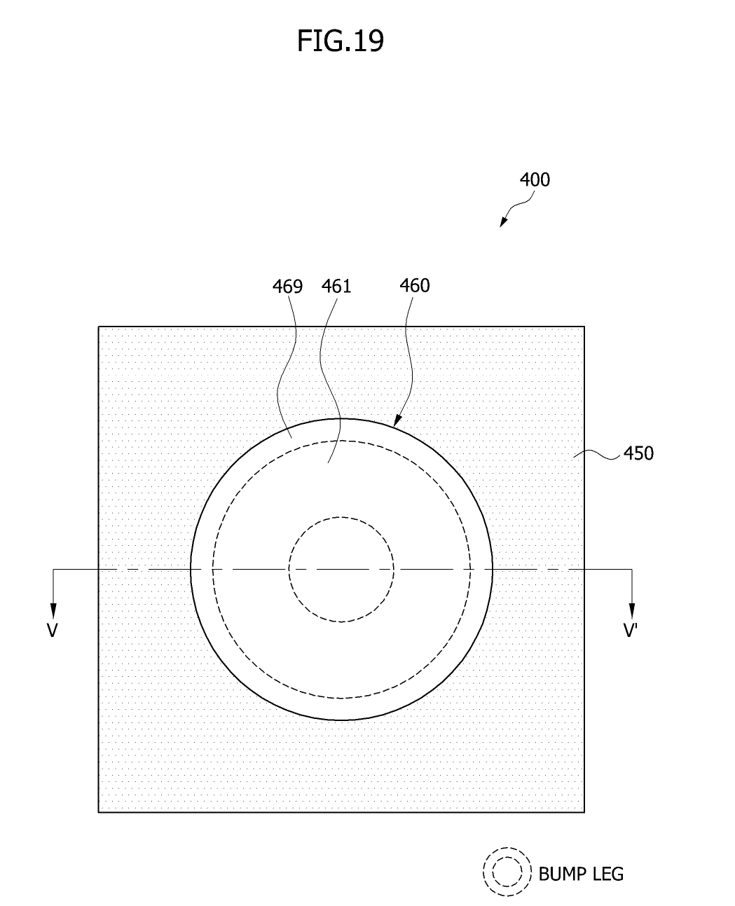

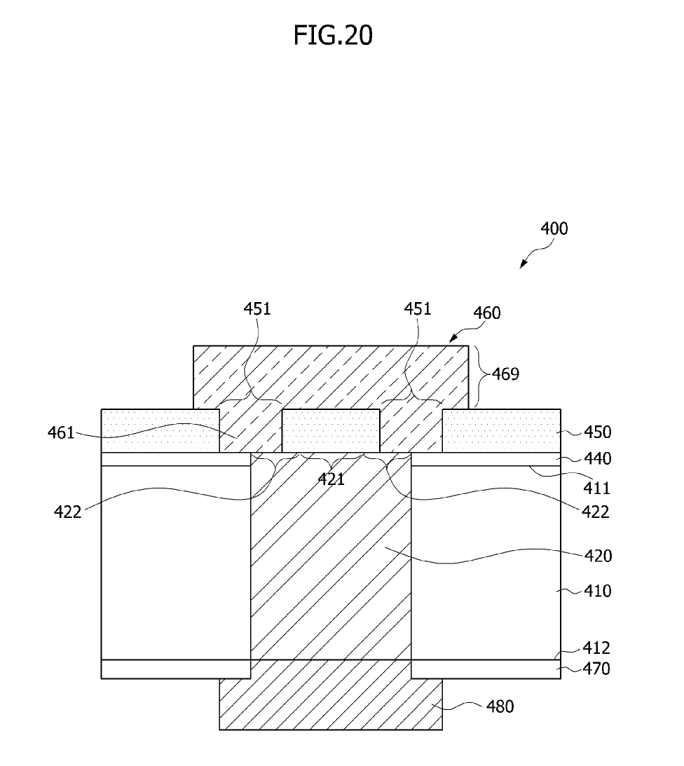

FIG. 19 is a plan view illustrating a semiconductor device 400 according to an embodiment of the present invention, and FIG. 20 is a cross-sectional view taken along a line V-V′ of FIG. 19. Referring to FIG. 19, the semiconductor device 400 includes a first insulation layer 450 and a bump 460 disposed on the first insulation layer 450. The bump 460 includes a bump leg 461 and a bump body 469. The bump body 469 is disposed on the bump leg 461 and a portion of the first insulation layer 450. The bump leg 461 may extend downward from a bottom surface of the bump body 469. In the present embodiment, the bump leg 461 includes a single bump leg. That is, the bump leg 461 has an annular shape in a plan view, as illustrated by dotted lines in FIG. 19. The bump leg 461 is disposed in an opening (not shown) that penetrates the first insulation layer 450.

Referring to FIGS. 19 and 20, the semiconductor device 400 further includes a device body 410 having a first surface 411 and a second surface 412 which are opposite to each other. Although not shown in the drawings, active elements such as transistors may be disposed in and/or on the device body 410. In addition, passive elements such as resistors and/or capacitors may be disposed in and/or on the device body 410. The device body 410 may be a semiconductor wafer (e.g., a silicon wafer) or a chip body which is obtained by dividing the semiconductor wafer into a plurality of chips through a sawing process. In another embodiment, the device body 410 is composed of another semiconductor material which is different from a silicon material.

A protection layer pattern 440 is disposed on the first surface 411 of the device body 410. A through electrode 420 is disposed to penetrate the device body 410 and the protection layer pattern 440. The through electrode 420 may include at least one metallic material. In an embodiment, the through electrode 420 includes a copper (Cu) material. Although not shown in the drawings, an insulation layer may be disposed between the through electrode 420 and the device body 410 to electrically insulate the through electrode 420 from the device body 410. Furthermore, a barrier layer may be disposed between the through electrode 420 and the device body 410 to prevent metal ions in the through electrode 420 from being diffused into the device body 410. If the barrier layer is formed of an insulation layer, only the barrier layer may be disposed between the through electrode 420 and the device body 410 to electrically insulate the through electrode 420 from the device body 410 and to prevent the metal ions in the through electrode 420 from being diffused into the device body 410.

A first end surface of the through electrode 420 is exposed at substantially the same level as that of a top surface of the protection layer pattern 440. The first insulation layer 450 is disposed on the top surface of the protection layer pattern 440 and the first end surface of the through electrode 420. In an embodiment, the first insulation layer 450 includes a polymer layer. In another embodiment, the first insulation layer 450 includes a nitride layer or an oxide layer.

As described with reference to FIG. 19, the bump 460 includes the leg 461 and the bump body 469. The bump leg 461 penetrates the first insulation layer 450 to contact a portion of the first end surface of the through electrode 420. In an embodiment, the bump 460 includes a metallic material such as a copper material. In another embodiment, the bump 460 includes a nickel material which is plated with a golden material.

The bump leg 461 fills an opening 451 that penetrates the first insulation layer 450 to expose a portion of the first end surface of the through electrode 420. As a result, the bump leg 461 contacts the first end surface of the through electrode 420. The top of the bump leg 461 may be level with the top surface of the first insulation layer 450. The bump body 469 is disposed on the top surface of the bump leg 461 and on a portion of the top surface of the first insulation layer 450. Thus, as illustrated in FIG. 20, the bump leg 461 is disposed between the bump body 469 and the through electrode 420. Meanwhile, in a certain region which is surrounded by the bump leg 461, the first insulation layer 450 is disposed between the bump body 469 and the through electrode 420.

Although FIG. 20 illustrates an embodiment in which the bump leg 461 contacts both the through electrode 420 and the protection layer pattern 440, embodiments are not limited thereto. In another embodiment, a bottom surface of the bump leg 461 contacts only the through electrode 420.

A second insulation layer 470 is disposed on the second surface 412 of the device body 410 to expose a second end surface of the through electrode 420. In an embodiment, the second insulation layer 470 includes a nitride material or an oxide material. The second end surface of the through electrode 420 is covered with a back-side bump 480. In an embodiment, the back-side bump 480 and the through electrode 420 constitute a single unified body without any heterogeneous junction therebetween. In another embodiment, the second end surface of the through electrode 420 is covered with another electrical connection member instead of the back-side bump 480.

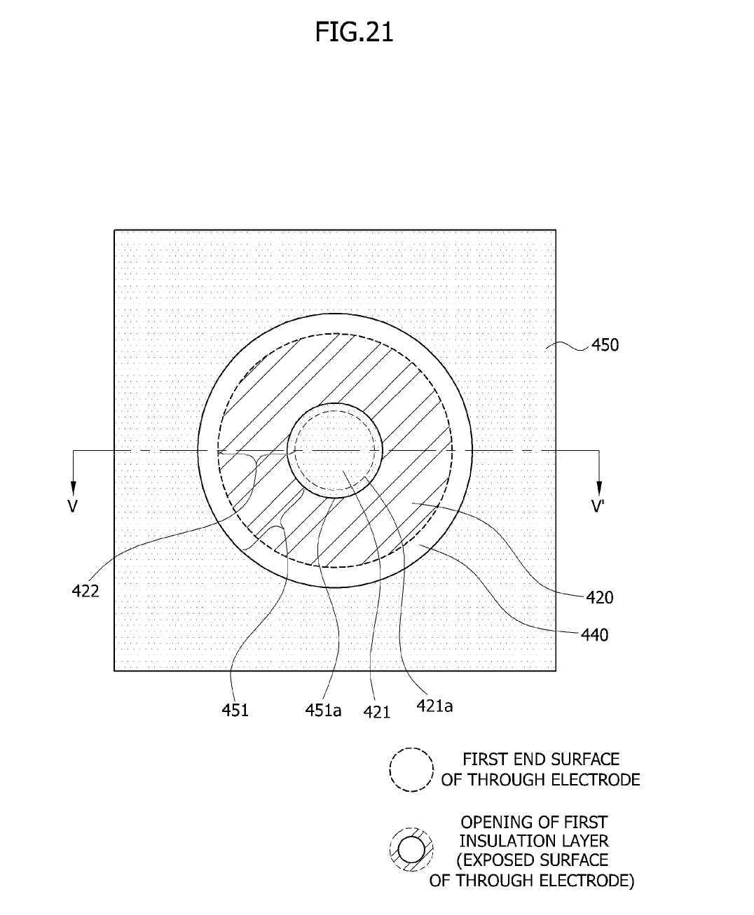

FIG. 21 is a plan view illustrating an array of the through electrode 420 and the first insulation layer 450 included in the semiconductor device 400 of FIGS. 19 and 20. A cross-sectional view taken along a line V-V′ of FIG. 21 may be the same as a part of the cross-sectional view of FIG. 20.

Referring to FIGS. 19, 20, and 21, the first end surface of the through electrode 420 has a circular shape in a plan view. However, in another embodiment, the first end surface of the through electrode 420 has a different shape from the circular shape in a plan view. The first end surface of the through electrode 420 includes a central portion 421 and an edge portion 422. The central portion 421 has a circular shape including a central point of the first end surface of the through electrode 420 in a plan view, and the edge portion 422 has an annular shape surrounding the central portion 421 in a plan view.

As described with reference to FIG. 20, the first insulation layer 450 has the opening 451. Although FIG. 21 illustrates an embodiment in which the opening 451 has an annular shape, embodiments are not limited thereto. In another embodiment, the opening 451 has a shape which is different from the annular shape. The opening 451 does not overlap with the central portion 421 of the through electrode 420 in a plan view. The opening 451 exposes a portion of the edge portion 422 of the through electrode 420 and a portion of the protection layer pattern 440. Thus, the central portion 421 of the through electrode 420 is covered with the first insulation layer 450. Furthermore, a portion of the edge portion 422 adjacent to the central portion 421 is also covered with the first insulation layer 450. Although FIGS. 20 and 21 illustrate an embodiment in which the opening 451 exposes a portion of the edge portion 422 of the through electrode 420, embodiments are not limited thereto. In another embodiment, the opening 451 exposes the entire surface of the edge portion 422 of the through electrode 420. In such a case, an inner circle 451a of the opening 451 having an annular shape may be close to a circle 421a defining the central portion 421 of the through electrode 420 in a plan view.

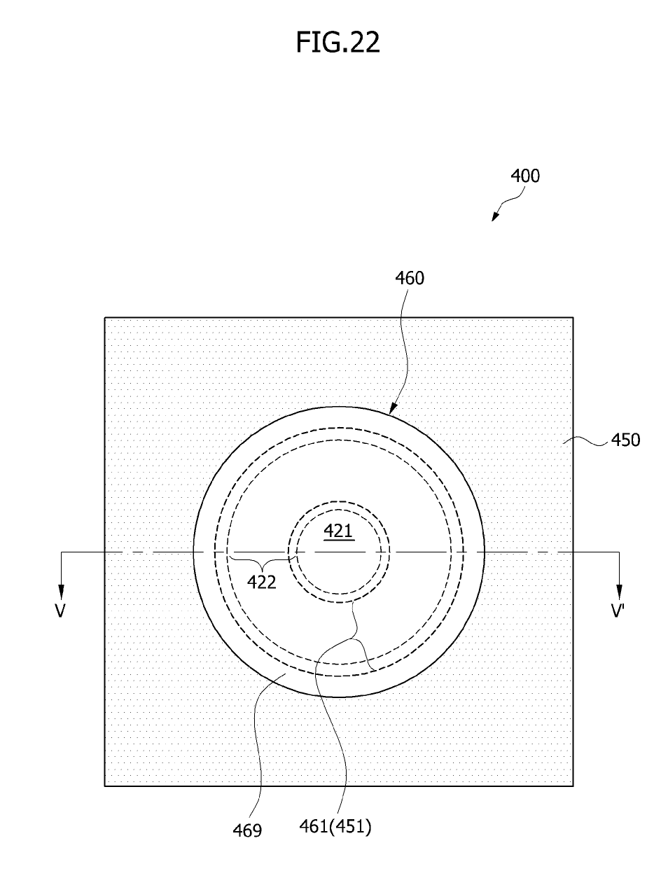

FIG. 22 is a plan view illustrating an array of the through electrode 420, the first insulation layer 450, and the bump 460 included in the semiconductor device 400 of FIGS. 19 and 20. A cross-sectional view taken along a line V-V′ of FIG. 22 may be substantially the same as the cross-sectional view of FIG. 20. Referring to FIGS. 19, 20, and 22, the bump 460 includes the bump leg 461, which is disposed on a portion of the through electrode 420 that is exposed by the opening 451, and the bump body 469, which is disposed on the bump leg 461 and a portion of the first insulation layer 450. The bump leg 461 may extend from a portion of the bottom surface of the bump body 469. Although the present embodiment illustrates a bump body 469 that has a circular shape in a plan view, embodiments are not limited thereto. In another embodiment, the bump body 469 may have a shape which is different from the circular shape in a plan view.

A shape of the bump leg 461 may be defined by a shape of the opening 451. Thus, if the opening 451 has an annular shape, the bump leg 461 may also have an annular shape. A bottom surface of the bump leg 461 may contact a portion of the edge portion 422 of the through electrode 420, which is exposed by the opening 451. An inner sidewall and an outer sidewall of the bump leg 461 may contact an inner sidewall and an outer sidewall of the opening 451, respectively. The top of the bump leg 461 may contact the bottom surface of the bump body 469. Thus, an electrical signal applied to the through electrode 420 may be transmitted via a path including the bump leg 461 and the bump body 469.

As described with reference to FIG. 21, the opening 451 may overlap with at least a portion of the edge portion 422 of the through electrode 420. However, the opening 451 does not overlap with the central portion 421 of the through electrode 420. Thus, while the bump leg 461 does not contact the central portion 421 of the through electrode 420, the bump leg 461 may contact at least a portion of the edge portion 422 of the through electrode 420. That is, no bump leg is disposed on the central portion 421 of the through electrode 420, but the first insulation layer 450 may be disposed on the central portion 421 of the through electrode 420. Since at least a portion of the edge portion 422 of the through electrode 420 is exposed by the opening 451, the edge portion 422 of the through electrode 420 may be covered with the first insulation layer 450 and the bump leg 461. The first insulation layer 450 may include a polymer material, and the bump leg 461 may include a metallic material. Thus, even though a stress is generated from the central portion 421 of the through electrode 420 due to a difference between a thermal expansion coefficient of the through electrode 420 and a thermal expansion coefficient of a material of a region adjacent to the through electrode 420 (e.g., device body), the first insulation layer 450 on the central portion 421 of the through electrode 420 may relieve the stress generated from the central portion 421 of the through electrode 420.

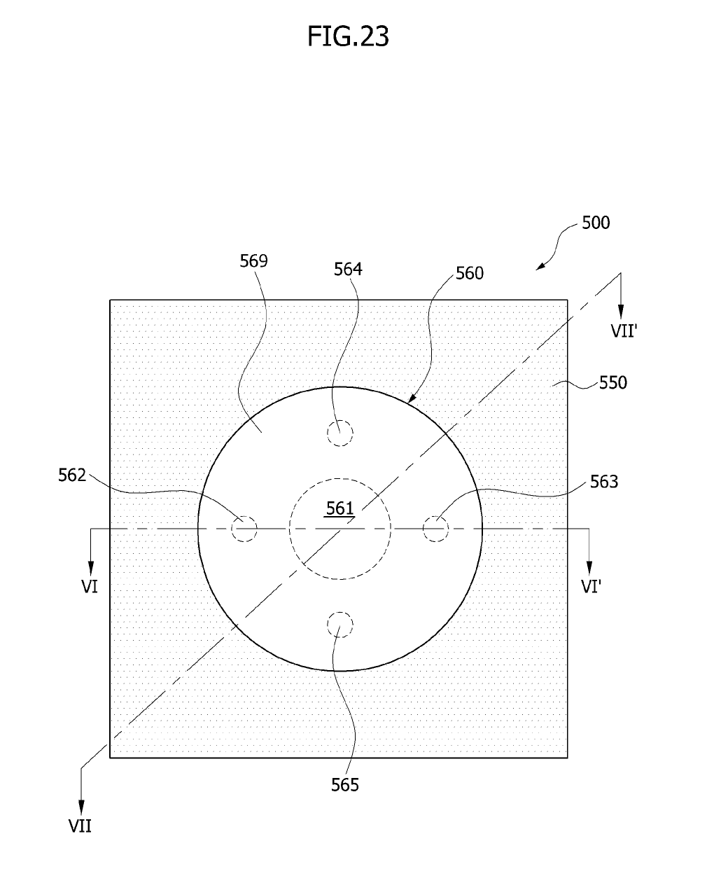

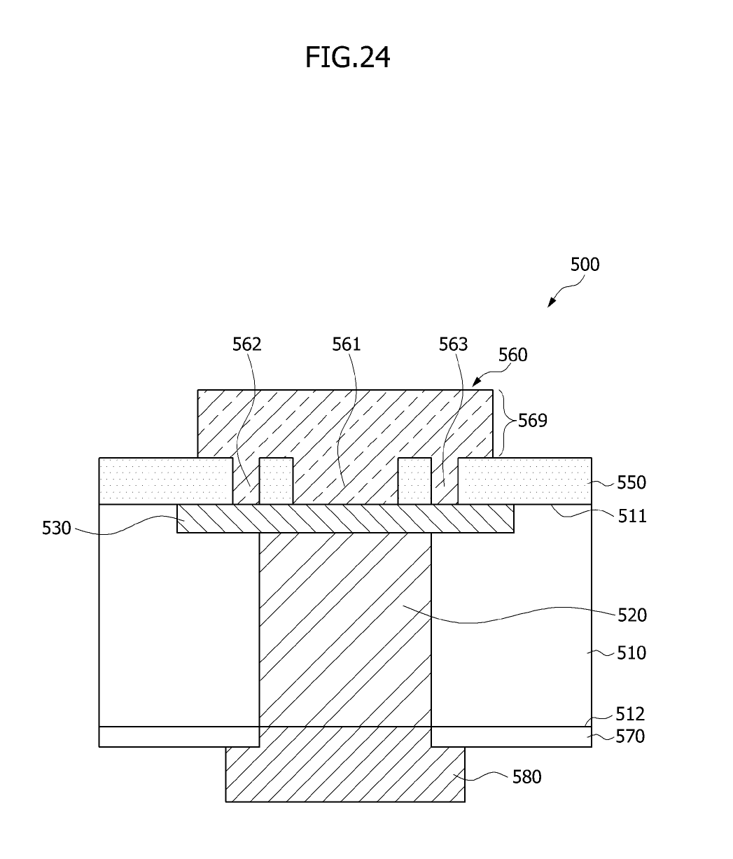

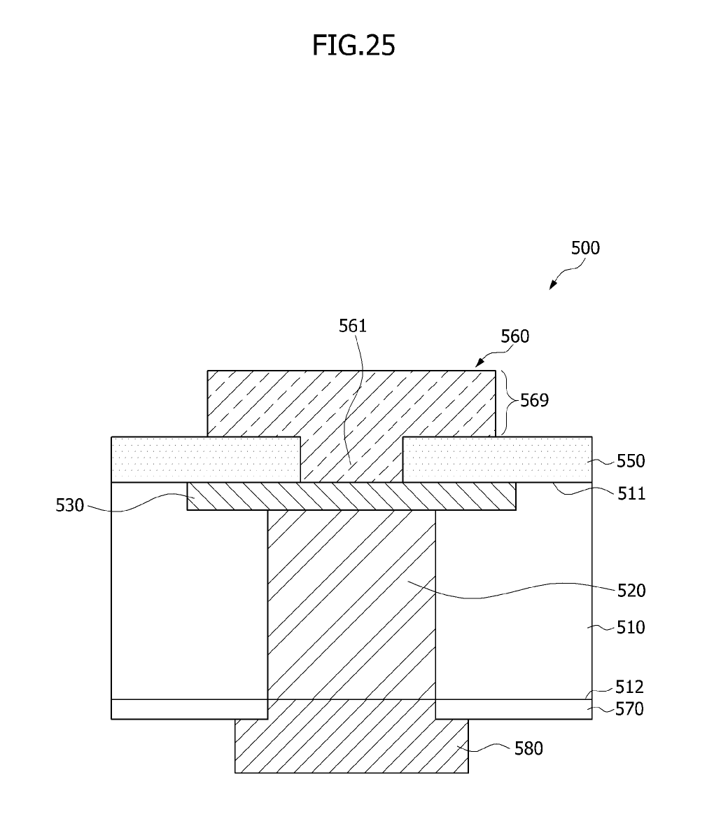

FIG. 23 is a plan view illustrating a semiconductor device 500 according to an embodiment of the present invention. FIG. 24 is a cross-sectional view taken along a line VI-VI′ of FIG. 23, and FIG. 25 is a cross-sectional view taken along a line VII-VII′ of FIG. 23. Referring to FIG. 23, the semiconductor device 500 includes a first insulation layer 550 and a bump 560. The bump 560 may include a plurality of bump legs 561, 562, 563, 564, and 565 and a bump body 569. The bump body 569 is disposed on the bump legs 561, 562, 563, 564, and 565 and a portion of the first insulation layer 550. The bump legs 561, 562, 563, 564, and 565 may include a central bump leg 561 disposed at a central region thereof and peripheral bump legs 562, 563, 564, and 565 arranged around the central bump leg 561. The bump legs 561, 562, 563, 564, and 565 may extend downward from a bottom surface of the bump body 569. The bump legs 561, 562, 563, 564, and 565 may be disposed to be spaced apart from each other. Although not shown in the top plan view of FIG. 23, the bump legs 561, 562, 563, 564, and 565 may be disposed in respective openings that penetrate the first insulation layer 550.

Referring to FIGS. 23, 24, and 25, the semiconductor device 500 includes a device body 510 having a first surface 511 and a second surface 512 which are opposite to each other. Although not shown in the drawings, active elements such as transistors may be disposed in and/or on the device body 510. In addition, passive elements such as resistors and/or capacitors may be disposed in and/or on the device body 510. The device body 510 may be a semiconductor wafer (e.g., a silicon wafer) or a chip body which is obtained by dividing the semiconductor wafer into a plurality of chips through a sawing process. In another embodiment, the device body 510 may be composed of another semiconductor material which is different from a silicon material.

A through electrode 520 is disposed to penetrate the device body 510. The through electrode 520 may include at least one metallic material. In an embodiment, the through electrode 520 may include a copper (Cu) material. Although not shown in the drawings, an insulation layer may be disposed between the through electrode 520 and the device body 510 to electrically insulate the through electrode 520 from the device body 510. Furthermore, a barrier layer may be disposed between the through electrode 520 and the device body 510 to prevent metal ions in the through electrode 520 from being diffused into the device body 510. If the barrier layer is formed of an insulation layer, only the barrier layer may be disposed between the through electrode 520 and the device body 510 to electrically insulate the through electrode 520 from the device body 510 and to prevent the metal ions in the through electrode 520 from being diffused into the device body 510.

A pad 530 is disposed in the device body 510 and on a top surface of the through electrode 520. The pad 530 is adjacent to the first surface 511 of the device body 510. The pad 530 may have a top surface that is disposed at substantially the same level as that of the first surface 511 of the device body 510.

The first insulation layer 550 is disposed on the first surface 511 of the device body 510 and the top surface of the pad 530. In an embodiment, the first insulation layer 550 includes a polymer layer. In another embodiment, the first insulation layer 550 includes a nitride layer or an oxide layer.

The first insulation layer 550 has at least one opening that exposes at least one portion of the pad 530. The bump legs 561, 562, 563, 564, and 565 are disposed in respective openings that penetrate the first insulation layer 550. Thus, the number of the openings may be equal to the number of the bump legs 561, 562, 563, 564, and 565, and the openings may have substantially the same shape as that of the bump legs 561, 562, 563, 564, and 565. However, embodiments are not limited thereto.

In an embodiment, a bottom surface of the pad 530 contacts the top surface of the through electrode 520. Hereinafter, the top surface of the through electrode 520 will be referred to as “a first end surface” and a bottom surface of the through electrode 520 that is opposite to the first end surface will be referred to as “a second end surface”. Although not shown in the drawings, in an embodiment, the first end surface of the through electrode 520 may be electrically coupled to the pad 530 via an interconnection layer which is disposed between the through electrode 520 and the pad 530. In an embodiment, the interconnection layer has a multi-layered metal structure.

The bump 560 is disposed on the first insulation layer 550 to fill the openings. In an embodiment, the bump 560 includes a metallic material such as a copper material. As described with reference to FIG. 23, the bump 560 includes the bump legs 561, 562, 563, 564, and 565 disposed in the openings and the bump body 569 disposed on the bump legs 561, 562, 563, 564, and 565 and covering a portion of the first insulation layer 550 around the openings. The bump legs 561, 562, 563, 564, and 565 fill the openings and contact the top surface of the pad 530. The bottom surface of the bump body 569, that is, the top of the bump legs 561, 562, 563, 564, and 565 may level with the top surface of the first insulation layer 550. Although the present embodiment illustrates five bump legs 561, 562, 563, 564, and 565, embodiments are not limited thereto. In another embodiment, the number of the bump legs is less or greater than five.

The bump body 569 is disposed on the top surfaces of the bump legs 561, 562, 563, 564, and 565 and on the portion of the top surface of the first insulation layer 550 around the openings. As illustrated in FIG. 24, the bump legs 561, 562, 563, 564, and 565 are disposed between the bump body 569 and the pad 530. In regions between the bump legs 561, 562, 563, 564, and 565, the first insulation layer 550 is disposed between the bump body 569 and the pad 530.

A second insulation layer 570 is disposed on the second surface 512 of the device body 510 to expose the second end surface of the through electrode 520. In an embodiment, the second insulation layer 570 includes a nitride material or an oxide material. The second end surface of the through electrode 520 is covered with a back-side bump 580. In an embodiment, the back-side bump 580 and the through electrode 520 constitute a single unified body without any heterogeneous junction therebetween. In another embodiment, the second end surface of the through electrode 520 may be covered with another electrical connection member instead of the back-side bump 580.

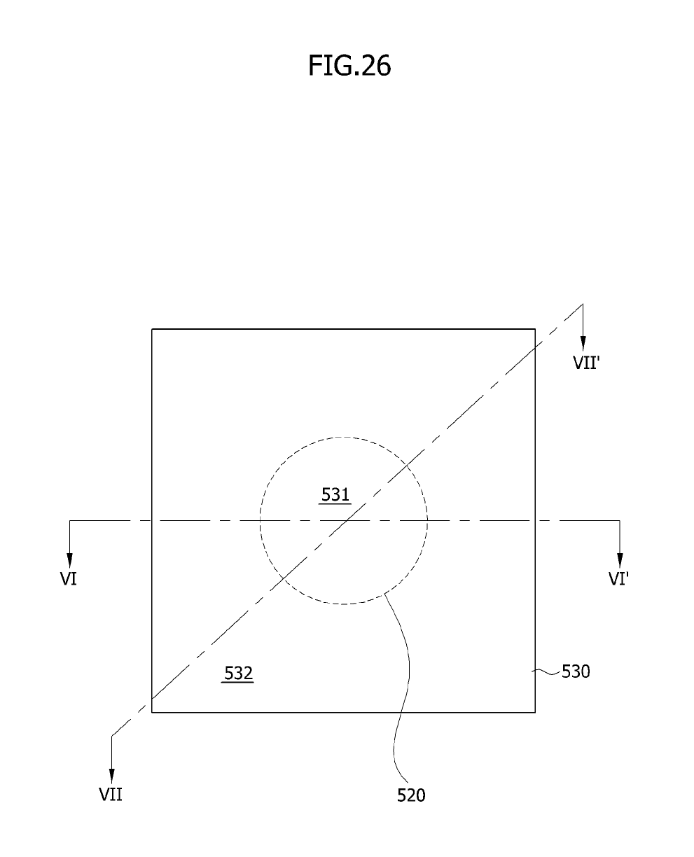

FIG. 26 is a plan view illustrating an array of the through electrode 520 and the pad 530 included in the semiconductor device 500 of FIGS. 23, 24, and 25. A cross-sectional view taken along a line VI-VI′ of FIG. 26 may be the same as a part of the cross-sectional view of FIG. 24, and a cross-sectional view taken along a line VII-VII′ of FIG. 26 may be the same as a part of the cross-sectional view of FIG. 25. Referring to FIGS. 23, 24, 25, and 26, the pad 530 has a rectangular shape in a plan view, and the through electrode 520 has a circular shape in a plan view. However, embodiments are not limited thereto. The pad 530 may have a different shape from the rectangular shape in a plan view, and the through electrode 520 may have a different shape from the circular shape in a plan view.

As described with reference to FIG. 24, the first end surface of the through electrode 520 overlaps with the pad 530. A planar area of a surface of the pad 530 may be greater than a planar area of the first end surface of the through electrode 520. Thus, the entire first end surface of the through electrode 520 overlaps with a portion of the pad 530 in a plan view as shown in FIG. 26. In an embodiment, during fabrication of the semiconductor device 500, the pad 530 is aligned with the through electrode 520 so that a central portion of the pad 530 overlaps with the first end surface of the through electrode 520. However, in another embodiment, the central portion of the pad 530 may not be aligned with the through electrode 520. In either case, the present invention may be applicable.

The pad 530 may include a first region that overlaps with the first end surface of the through electrode 520 and a second region that does not overlap with the first end surface of the through electrode 520. In the present embodiment, the first region may be defined as an overlap region 531, and the second region may be defined as a non-overlap region 532. In an embodiment, a bottom surface of the pad 530 in the overlap region 531 may directly contact the first end surface of the through electrode 520. In another embodiment, the first end surface of the through electrode 520 may be electrically coupled to the bottom surface of the pad 530 in the overlap region 531 via an interconnection layer which is disposed between the through electrode 520 and the pad 530. The interconnection layer may have a multi-layered metal structure. A planar shape of the overlap region 531 of the pad 530 may be substantially the same as a planar shape of the first end surface of the through electrode 520.

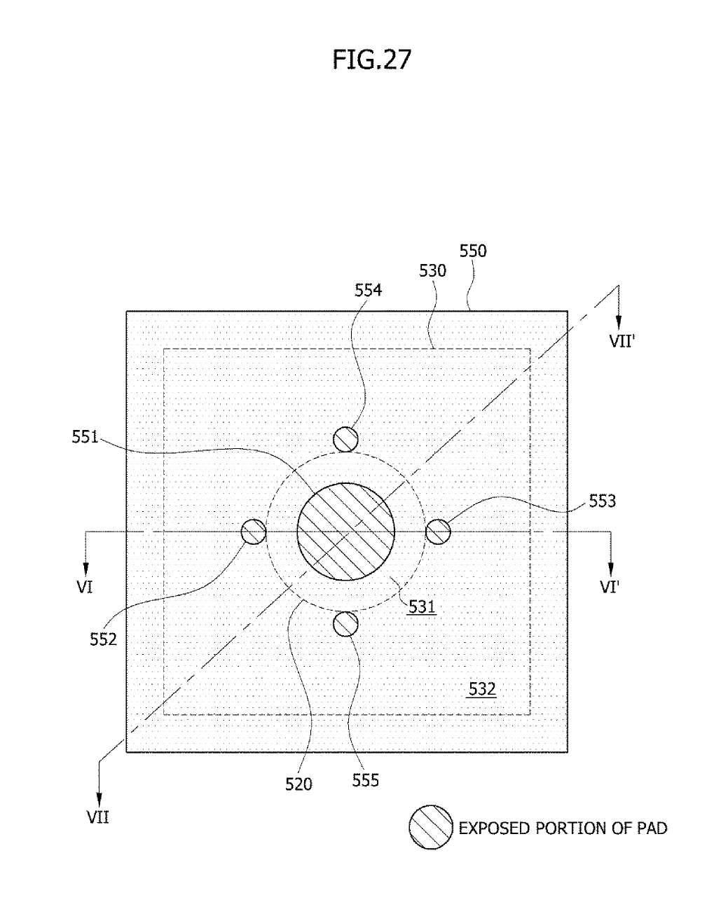

FIG. 27 is a plan view illustrating an array of the through electrode 520, the pad 530, and the first insulation layer 550 included in the semiconductor device 500 of FIGS. 23, 24, and 25. A cross-sectional view taken along a line VI-VI′ of FIG. 27 may be the same as a part of the cross-sectional view of FIG. 24, and a cross-sectional view taken along a line VII-VII′ of FIG. 27 may be the same as a part of the cross-sectional view of FIG. 25. Referring to FIGS. 23, 24, 25, and 27, the first insulation layer 550 has a plurality of openings 551, 552, 553, 554, and 555 that expose portions of the pad 530. Although FIG. 27 illustrates an embodiment in which each of the openings 551, 552, 553, 554, and 555 has a circular shape, embodiments are not limited thereto. In another embodiment, each of the openings 551, 552, 553, 554, and 555 may have a shape which is different from the circular shape. The remaining portion of the pad 530, other than the portions of the pad 530 which are exposed by the openings 551, 552, 553, 554, and 555, may be covered with the first insulation layer 550. The opening 551 is disposed in the overlap region 531 in a plan view, and the remaining openings 552, 553, 554, and 555 are disposed in the non-overlap region 532 in a plan view. In another embodiment, at least one of the openings 552, 553, 554, and 555 may also be disposed in a portion of the overlap region 531 in a plan view.

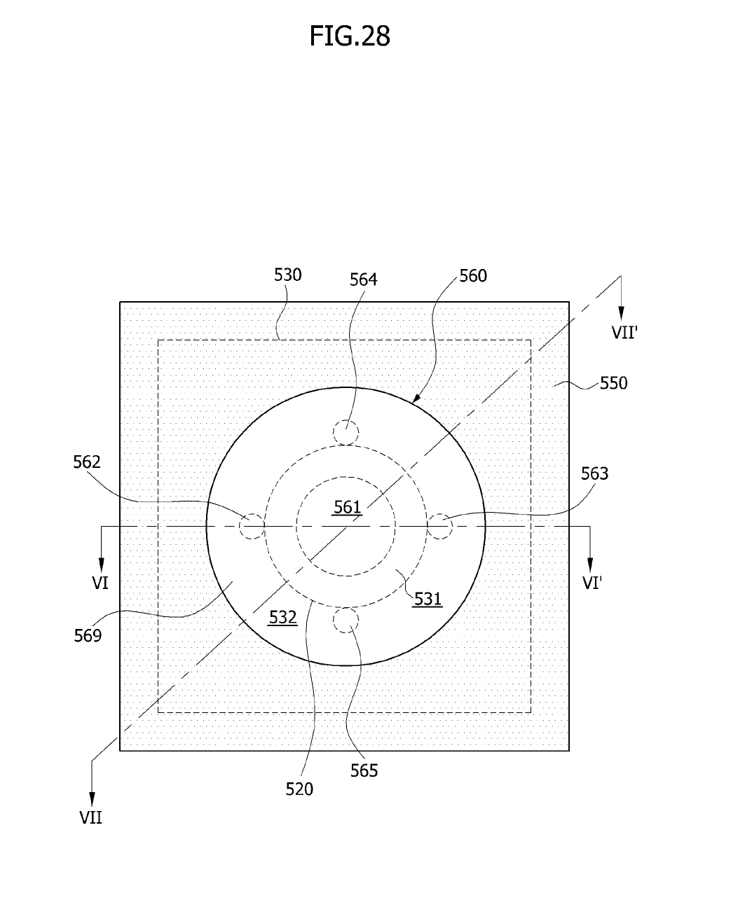

FIG. 28 is a plan view illustrating an array of the through electrode 520, the pad 530, the first insulation layer 550, and the bump 560 included in the semiconductor device 500 of FIGS. 23, 24, and 25. A cross-sectional view taken along a line VI-VI′ of FIG. 28 may be substantially the same as the cross-sectional view of FIG. 24, and a cross-sectional view taken along a line VII-VII′ of FIG. 28 may be substantially the same as the cross-sectional view of FIG. 25. Referring to FIGS. 23, 24, 25, and 28, the bump 560 is disposed on a top surface of the first insulation layer 550 and on portions of the pad 530 exposed by the openings 551, 552, 553, 554, and 555. As described with reference to FIGS. 23, 24, and 25, the bump 560 may include the bump legs 561, 562, 563, 564, and 565 disposed in the openings 551, 552, 553, 554, and 555 of the first insulation layer 550, respectively, and the bump body 569 disposed on the bump legs 561, 562, 563, 564, and 565 and a portion of the first insulation layer 550 around the openings 551, 552, 553, 554, and 555.

The bump leg 561 disposed centrally among the bump legs 561, 562, 563, 564, and 565 may be referred to as a central bump leg, and the other bump legs 562, 563, 564, and 565 disposed around the central bump leg 561 may be referred to as peripheral bump legs. In the present embodiment, the bump body 569 may have a circular shape in a plan view. However, in another embodiment, the bump body 569 may have a shape which is different from the circular shape in a plan view.

The bump legs 561, 562, 563, 564, and 565 may be disposed to fill respective openings 551, 552, 553, 554, and 555 that penetrate the first insulation layer 550. Thus, shapes of the bump legs 561, 562, 563, 564, and 565 may be defined by shapes of the openings 551, 552, 553, 554, and 555, respectively. For example, if each of the openings 551, 552, 553, 554, and 555 has a cylindrical shape, each of the bump legs 561, 562, 563, 564, and 565 may have a columnar pillar shape. Furthermore, sidewalls of the bump legs 561, 562, 563, 564, and 565 may contact sidewalls of the openings 551, 552, 553, 554, and 555, respectively. Bottom surfaces of the bump legs 561, 562, 563, 564, and 565 may contact the top surface of the pad 530 exposed by the openings 551, 552, 553, 554, and 555. In particular, a bottom surface of the central bump leg 561 may contact the overlap region 531 of the pad 530, and bottom surfaces of the peripheral bump legs 562, 563, 564, and 565 may contact the non-overlap region 532 of the pad 530. In another embodiment, at least one of the peripheral bump legs 562, 563, 564, and 565 may also contact the overlap region 531 of the pad 530. In such a structure, a stress may be generated from the first end surface of the through electrode 520 due to a difference between a thermal expansion coefficient of the through electrode 520 and a thermal expansion coefficient of a material of a region adjacent to the through electrode 520. The stress may cause a contact failure between the central bump leg 561 and the pad 530 (e.g., device body). However, according to an embodiment, since a stress applied to the peripheral bump legs 562, 563, 564, and 565 may be less than the stress applied to the central bump leg 561, physical contact states between the peripheral bump legs 562, 563, 564, and 565 and the pad 530 become more stable than a physical contact state between the central bump leg 561 and the pad 530, thus providing an electrical path between the bump 560 and the through electrode 520 without any defects.

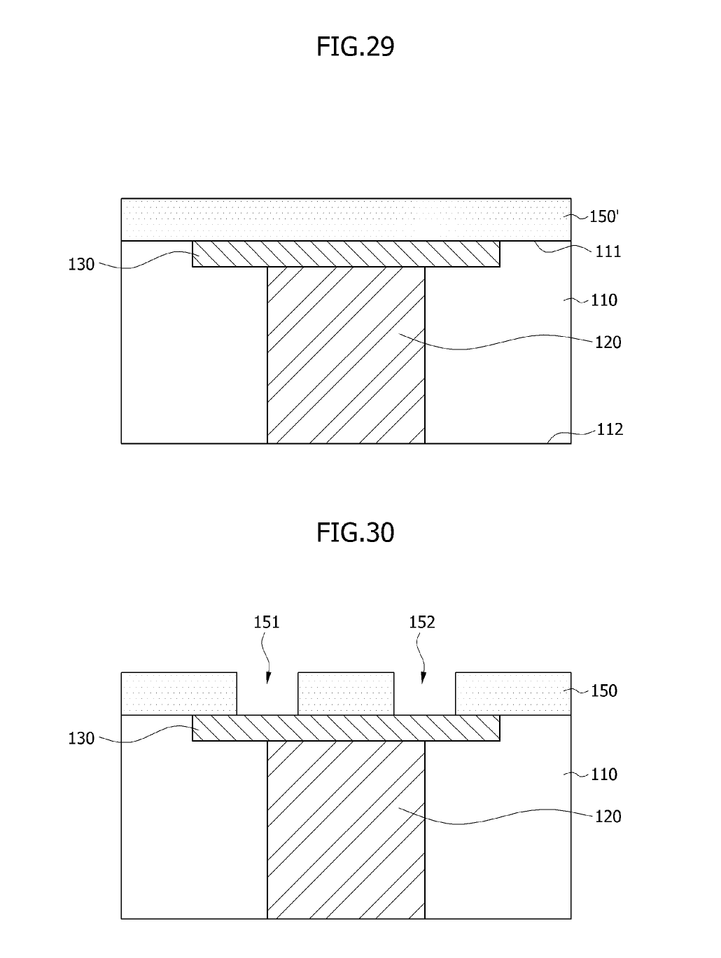

FIGS. 29, 30, and 31 are cross-sectional views illustrating a method of fabricating a semiconductor device according to an embodiment of the present invention. As illustrated in FIG. 29, a device body 110 having a first surface 111 and a second surface 112 which are opposite to each other is provided. Active elements (not shown) such as transistors may be disposed in and/or on the device body 110. In addition, passive elements (not shown) such as resistors and/or capacitors may be disposed in and/or on the device body 110. The device body 110 may be a semiconductor wafer (e.g., a silicon wafer) or a chip body which is obtained by dividing the semiconductor wafer into a plurality of chips through a sawing process. In another embodiment, the device body 110 may be composed of another semiconductor material which is different from a silicon material. After that, a through electrode 120 is formed to penetrate the device body 110. The through electrode 120 may be formed to include at least one metallic material. In an embodiment, the through electrode 120 includes a copper (Cu) material. After forming the through electrode 120, an upper portion of the through electrode 120 and a portion of the device body 110 surrounding the upper portion of the through electrode 120 are removed by a predetermined depth to form a trench. Subsequently, a pad 130 is formed by filling the trench. In an embodiment, the pad 130 is formed of a metallic material. Although not shown in the drawings, after forming the trench and before forming the pad 130, an interconnection layer may be formed on the through electrode 120 and the first surface 111 of the device body 110. In such a case, the pad 130 may be formed on an uppermost metal layer of the interconnection layer. After forming the pad 130, an insulation layer 150′ is formed on the first surface 111 of the device body 110 and a top surface of the pad 130. In an embodiment, the insulation layer 150′ is formed of a polymer layer. In another embodiment, the insulation layer 150′ is formed of a nitride layer or an oxide layer.

Subsequently, as illustrated in FIG. 30, the insulation layer 150′ is patterned to form a patterned insulation layer 150 including openings 151 and 152 that expose portions of the pad 130. The openings 151 and 152 may be formed to have one of various shapes. In the present embodiment, the plurality of openings 151, 152, 153, and 154 may be formed to expose edge portions of the pad 130 that do not overlap with a central portion of the through electrode 120, as described with reference to FIG. 5. However, in another embodiment, the insulation layer 150′ may be patterned to form the opening 251, which has an annular shape that does not overlap with the central portion of the pad 130, as described with reference to FIG. 13. In still another embodiment, the insulation layer 150′ may be patterned to form the opening 551, which expose a central portion of the pad 530 that overlaps with the through electrode 520, and the openings 552, 553, 554, and 555, which expose edge portions of the pad 530 that do not overlap with the through electrode 520, as described with reference to FIG. 27.

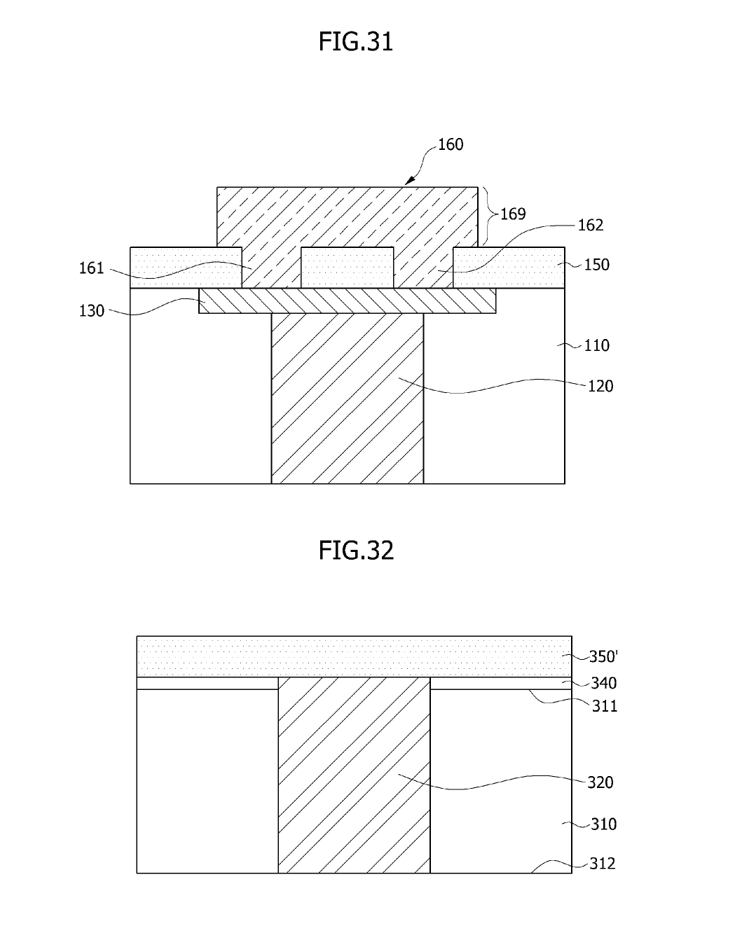

Subsequently, as illustrated in FIG. 31, a bump 160 is formed to fill the openings 151, 152, 153, and 154 and to cover a top surface of the patterned insulation 150 around the openings 151, 152, 153, and 154. In an embodiment, the bump 160 is formed of a metallic material such as a copper material. The bump 160 may be formed using a plating process. The bump 160 is formed to include bump legs 161, 162, 163, and 164 filling the openings 151, 152, 153, and 154, respectively, and a bump body 169 covering top surfaces of the bump legs 161, 162, 163, and 164 and a portion of the patterned insulation 150 around the openings 151, 152, 153, and 154.

FIGS. 32, 33, and 34 are cross-sectional views illustrating a method of fabricating a semiconductor device according to another embodiment of the present invention. As illustrated in FIG. 32, a device body 310 having a first surface 311 and a second surface 312 which are opposite to each other is provided. Active elements (not shown) such as transistors may be disposed in and/or on the device body 310. In addition, passive elements (not shown) such as resistors and/or capacitors may be disposed in and/or on the device body 310. The device body 310 may be a semiconductor wafer (e.g., a silicon wafer) or a chip body obtained by dividing the semiconductor wafer into a plurality of chips through a sawing process. In some embodiments, the device body 310 may be composed of another semiconductor material which is different from a silicon material.

After the device body 310 is formed, a protection layer 340 is formed on the first surface 311 of the device body 310, and a through electrode 320 is formed to penetrate the device body 310 and the protection layer 340. The through electrode 320 may be formed to include at least one metallic material. In an embodiment, the through electrode 320 is formed to include a copper (Cu) material. After forming the through electrode 320, an insulation layer 350′ is formed on a top surface of the through electrode 320 and a top surface of the protection layer 340. In an embodiment, the insulation layer 350′ is formed of a polymer layer. In another embodiment, the insulation layer 350′ is formed of a nitride layer or an oxide layer.

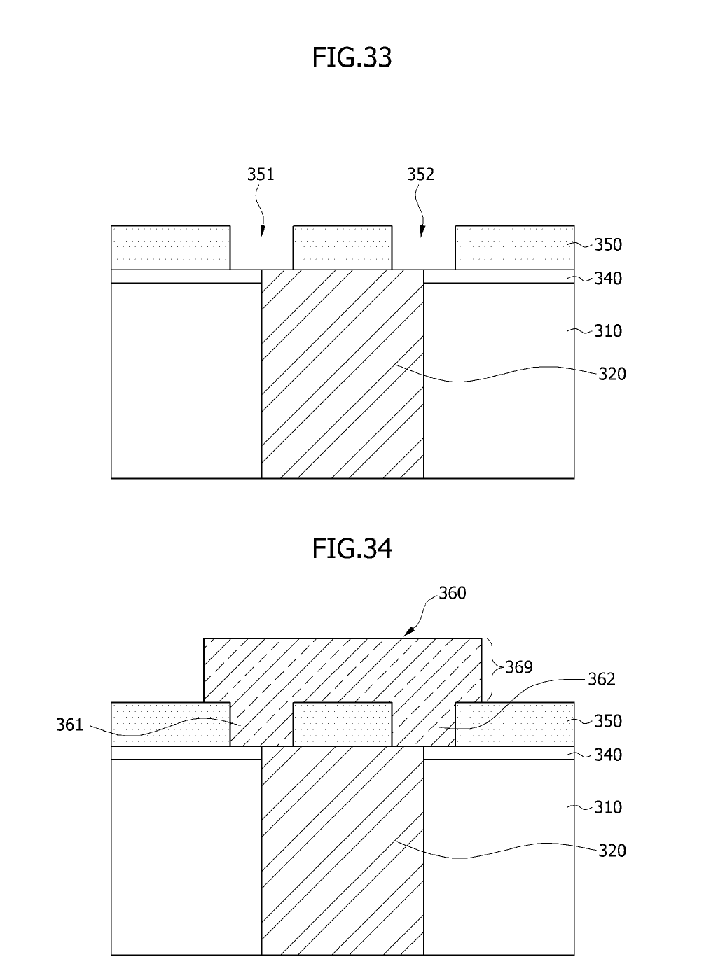

Subsequently, as illustrated in FIG. 33, the insulation layer 350′ is patterned to form a patterned insulation layer 350 including openings 351 and 352 that expose portions of the through electrode 320. The openings 351 and 352 may be formed to have one of various shapes. In the present embodiment, the plurality of openings 351, 352, 353, and 354 is formed to expose edge portions of the through electrode 320, as described with reference to FIG. 17. However, in another embodiment, the insulation layer 350′ may be patterned to form the opening 451 that has an annular shape to expose an edge portion of the through electrode 420, as described with reference to FIG. 21.

Subsequently, as illustrated in FIG. 34, a bump 360 is formed to fill the openings 351, 352, 353, and 354 and to cover a top surface of the patterned insulation 350 around the openings 351, 352, 353, and 354. In an embodiment, the bump 360 may be formed of a metallic material such as a copper material. The bump 360 may be formed using a plating process. The bump 360 is formed to include bump legs 361, 362, 363, and 364 filling the openings 351, 352, 353, and 354, respectively, and a bump body 369 covering top surfaces of the bump legs 361, 362, 363, and 364 and a portion of the patterned insulation 350 around the openings 351, 352, 353, and 354.

A semiconductor device having a through electrode in accordance with an embodiment described above may be applied to various electronic systems.

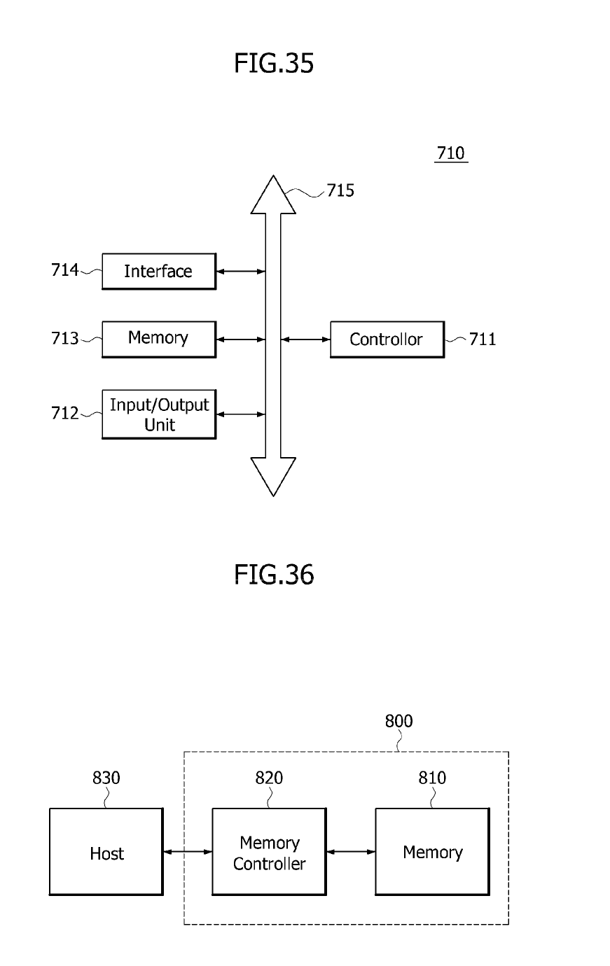

FIG. 35 illustrates an electronic system 710 that may include any of the semiconductor devices described above. The electronic system 710 includes a controller 711, an input/output unit 712, and a memory 713. The controller 711, the input/output unit 712, and the memory 713 may be coupled with one another via a bus 715, which provides a data transmission path between components.

The controller 711 may include at least one of one or more microprocessors, one or more digital signal processors, one or more microcontrollers, one or more logic devices, and so on. The controller 711 and/or the memory 713 may include one or more semiconductor devices according to an embodiment of the present invention. The input/output unit 712 may include at least one selected among a keypad, a keyboard, a display device, a touch screen, and so forth. The memory 713 may store data and/or commands to be executed by the controller 711.

The memory 713 may include a volatile memory device, such as DRAM, and/or a nonvolatile memory device, such as flash memory. For example, the flash memory may be mounted to an information processing system such as a mobile terminal or a desktop computer. The flash memory may constitute a solid state disk (SSD). Thus, the electronic system 710 may store a large amount of data in the flash memory.

The electronic system 710 may also include an interface 714 suitable for transmitting and receiving data to and from a communication network. The interface 714 may be a wired or wireless interface, and include an antenna or a wired or wireless transceiver.

The electronic system 710, therefore, may be a mobile system or device, a personal computer or laptop, an industrial computer or server, or any other logic or computing system. For example, the mobile system or device may be any one of a personal digital assistant (PDA), a portable computer, a tablet computer, a mobile phone, a smart phone, a wireless phone, a laptop computer, a memory card, a digital music system and an information transmission/reception system.

In some embodiments, the electronic system 710 may be utilized by a communication system, such as a CDMA (code division multiple access), GSM (global system for mobile communications), NADC (North American digital cellular), E-TDMA (enhanced-time division multiple access), WCDMA (wideband code division multiple access), CDMA2000, LTE (long term evolution), and/or Wibro (wireless broadband Internet).

FIG. 36 illustrates a memory card 800 that may include any of the semiconductor devices described above. The memory card 800 includes a memory 810 and a memory controller 820. The memory 810 and the memory controller 820 may store data and/or read stored data.

The memory 810 may include a nonvolatile memory device, and the memory controller 820 may control the memory 810 such that data is read out or data is stored in response to a read/write request from a host 830.

Embodiments have been disclosed above for illustrative purposes. Those skilled in the art will appreciate that various modifications, additions and substitutions are possible, without departing from the scope and spirit of the inventive concept as disclosed in the accompanying claims.

What is claimed is:

1. A semiconductor device comprising:
a through electrode penetrating a device body;
a pad disposed over an end of the through electrode, the pad having an overlap region that overlaps with a central portion of the end of the through electrode; and
a bump disposed over the pad without contacting the overlap region of the pad.

2. The semiconductor device of claim 1, wherein the overlap region is a first overlap region, and
wherein the pad further comprises a second overlap region that overlaps with an edge portion of the end of the through electrode.

3. The semiconductor device of claim 1, wherein the through electrode includes a copper material.

4. The semiconductor device of claim 2,
wherein the first overlap region has a circular shape in a plan view; and
wherein the second overlap region has an annular shape surrounding the first overlap region in a plan view.

5. The semiconductor device of claim 2, wherein the bump includes:
a plurality of bump legs disposed to be spaced apart from each other and to contact the second overlap region of the pad; and
a bump body disposed on the bump legs.

6. The semiconductor device of claim 5, wherein the bump legs are disposed to be symmetrical with respect to a central point of the through electrode in a plan view.

7. The semiconductor device of claim 5, wherein each of the bump legs contacts a portion of the second overlap region of the pad.

8. The semiconductor device of claim 5, further comprising an insulation layer disposed between the bump legs in the second overlap region.

9. The semiconductor device of claim 5, further comprising an insulation layer disposed between a top surface of the pad and a bottom surface of the bump body in the first overlap region.

10. The semiconductor device of claim 9, wherein the insulation layer includes a polymer material.

11. The semiconductor device of claim 1, wherein the bump includes:
a bump leg disposed over the pad without contacting the pad in the overlap region; and
a bump body disposed on the bump leg.

12. The semiconductor device of claim 11, wherein the bump leg has an annular shape in a plan view that surrounds the overlap region.

13. The semiconductor device of claim 11, further comprising an insulation layer disposed between a top surface of the pad and a bottom surface of the bump body in the overlap region.

14. A semiconductor device comprising:
a through electrode penetrating a device body;
a pad disposed over an end of the through electrode, the pad having an overlap region that overlaps with the through electrode and a non-overlap region that surrounds the overlap region in a plan view; and
a bump disposed over the pad,
wherein the bump includes a central bump leg disposed over the overlap region of the pad, a plurality of peripheral bump legs disposed over the non-overlap region of the pad, and a bump body disposed on the central bump leg and the plurality of peripheral bump legs.

15. A semiconductor device comprising:
a through electrode penetrating a device body; and
a bump disposed to contact an edge portion of an end surface of the through electrode without contacting a central portion of the end surface of the through electrode.

16. The semiconductor device of claim 15, wherein the bump includes:
a plurality of bump legs spaced apart from each other and in contact with the edge portion of the end surface of the through electrode; and
a bump body disposed on the bump legs.

17. The semiconductor device of claim 16, further comprising an insulation layer disposed between the central portion of the end surface of the through electrode and a bottom surface of the bump body.

18. The semiconductor device of claim 17, wherein the insulation layer includes a polymer material.

19. The semiconductor device of claim 15, wherein the bump includes:
a bump leg having an annular shape in a plan view that surrounds the central portion of the end surface of the through electrode; and
a bump body disposed on the bump leg.

20. The semiconductor device of claim 19, further comprising an insulation layer disposed between the central portion of the end surface of the through electrode and a bottom surface of the bump body.
